(19) United States
(12) Patent Application Publication
(10) Pub. No.: US 2005/0141302 A1
(43) Pub. Date: Jun. 30, 2005

(54) Method for surveying layout of information devices

(75) Inventors: Yoshiharu Maeda, Kawasaki (JP); Kuniharu Takayama, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/064,983

(22) Filed: Feb. 25, 2005

Related U.S. Application Data
(63) Continuation of application No. PCT/JP03/00309, filed on Jan. 16, 2003.

(51) Int. Cl. G11C 29/00

(52) U.S. Cl. 365/200

(57) ABSTRACT

The layout survey apparatus includes a calculating unit that calculates a distance to a plurality of other devices respectively on the basis of a reception field intensity; a creating unit that creates location data of the apparatus and the devices on the basis of the distance calculated; an acquiring unit that acquires location data of the apparatus and the devices from the devices respectively; and a creating unit that creates layout information for displaying physical layout of the apparatus and the devices on the basis of the location data created and the location data acquired.

### BACKGROUND OF THE INVENTION

1) Field of the Invention

The present invention relates to a technology for surveying layout of information devices such as computers, peripheral devices, etc.

2) Description of the Related Art

A wide range of information devices such as personal computers (PCs), personal digital assistants (PDAs), and peripheral devices (such as printers, scanners, routers, etc.) have been conventionally used for large volumes of information exchange between IT devices (users) by means of connecting to a network.

In recent years even household appliances such as the refrigerators and microwave ovens have come to be connected to the network. Such appliances fall under the category of digital consumer electronics.

Each information device (called a node) connected to the network is given a unique ID or name to distinguish it from the other information devices. For instance, an information device connected to an Internet Protocol (IP) network such as the Internet or the Intranet is assigned an IP address that corresponds to an address on the IP network.

To help users avoid having to commit to memory a multi-digit numerical value, a domain name system (DNS) is followed in IP network wherein each information device is assigned a host name consisting of alphanumerical characters or symbols, and a correspondence is established between the host name and the IP address to enable mutual reference between the host name and the IP address.

Apart from the IP address, a media access control (MAC) address is set as a hardware address to recognize the host on the network.

The use of wireless systems of communication in network connection has been gaining ground in recent years. Wireless local area network (LAN) that uses a part of Ethernet (™) standards, Bluetooth which is a wireless transmission system that operates in the 2.4 GHz band, etc. are examples of wireless methods of communication used in network connection.

Wireless LAN and Bluetooth are used as means of providing Internet connectivity to portable information devices such as notebook PCs or PDAs. Wireless LAN is also used as a hot spot that provides outdoor spots that can be connected to the Internet. These hotspots may for instance be installed in stations, stores, etc.

Conventionally, ID such as the IP address or the host name is used for identifying where on the network a particular information device is.

However, conventionally it is difficult to identify where the information devices are spatially located indoors or outdoors (for example, if indoors, on which desk). When the information devices are to be connected to the network and used, then an IP address/information device name correspondence table 10 shown in FIG. 39, a network configuration diagram 20 shown in FIG. 40, and an office layout drawing 30 shown in FIG. 41 are required.

The IP address/information device name correspondence table 10, the network configuration diagram 20, and the office layout drawing 30 are created by hand, mainly with an object of network construction or network management.

Generally, if the network configuration diagram 20 and the office layout drawing 30 are up-to-date, the layout (spatial locations) of the information devices can be accurately determined.

However, up-to-date layout (spatial locations) of the information devices cannot be accurately determined in the conventional methods because of the reasons listed below.
Information devices such as the Notebook PCs, PDAs, etc. can be shifted.
Semi-fixed information devices such as desktop PCs or printers can also be shifted.
Information devices are added and removed.

The following disadvantages result if the layout of the information devices is uncertain.
The location (current location) of an information device cannot be determined even though the IP address corresponding to the information device is known.
Conversely, the IP address of the information device at hand is not known unless looking at the IP address setting.
If both the IP address and the information device name are not known, information cannot be sent to the information device at hand.

### SUMMARY OF THE INVENTION

It is an object of the present invention to at least solve the problems in the conventional technology.

A computer-readable recording medium according to an aspect of the present invention stores a computer program that causes a computer to execute: calculating a distance between the computer and a plurality of other devices respectively on the basis of a reception field intensity; creating location data of the computer and the devices on the basis of the distance calculated; acquiring location data of the computer and the devices from the devices respectively; and creating layout information for displaying physical layout of the computer and the devices on the basis of the location data created and the location data acquired.

A computer-readable recording medium according to another aspect of the present invention stores a computer program that causes a computer to execute: calculating a distance and a direction between the computer and a plurality of other devices respectively on the basis of a reception field intensity; creating location data of the computer and the devices on the basis of the distance and the direction calculated; acquiring location data of the computer and the devices from the devices respectively; and creating layout information for displaying physical layout of the computer and the devices on the basis of the location data created and the location data acquired.

A layout survey apparatus according to still another aspect of the present invention includes a calculating unit that calculates a distance to a plurality of other devices respectively on the basis of a reception field intensity; a creating unit that creates location data of the apparatus and the devices on the basis of the distance calculated; an acquiring unit that acquires location data of the apparatus and the devices from the devices respectively; and a creating unit that creates layout information for displaying physical layout of the apparatus and the devices on the basis of the location data created and the location data acquired.

A layout survey method according to still another aspect of the present invention includes calculating a distance between a first device and a plurality of second devices respectively on the basis of a reception field intensity; creating location data of the first device and the second devices on the basis of the distance calculated; acquiring location data of the first device and the second devices from the second devices respectively; and creating layout information for displaying physical layout of the first device and the second devices on the basis of the location data created and the location data acquired.

A layout survey system according to still another aspect of the present invention includes a master device and a plurality of slave devices, and the master device includes a calculating unit that calculates a distance between the master device and the slave devices respectively on the basis of a reception field intensity; a creating unit that creates location data of the master device and the slave devices on the basis of the distance calculated; an acquiring unit that acquires location data of the master device and the slave devices from the slave devices respectively; and a creating unit that creates layout information for displaying physical layout of the master device and the slave devices on the basis of the location data created and the location data acquired.

The other objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a block diagram of a layout survey apparatus according to a first embodiment of the present invention;

FIG. 2 is a drawing of an office layout that indicates the positions of information devices 100₁ through 100₆ shown in FIG. 1;

FIG. 3 is a drawing of an information device attribute data 121 stored in an information device attribute data storing unit 120 shown in FIG. 1;

FIG. 4 is a drawing of a matching target information 131 stored in a matching target information storing unit 130 shown in FIG. 1;

FIG. 5 is a drawing of an information device combination table 104a created by a distance computing unit 104 shown in FIG. 1;

FIG. 6 is a drawing of a reference information device location data 141₃ created by a reference information device location data creating unit 105 shown in FIG. 1;

FIG. 7 is a schematic diagram of the reference information device location data 141₃;

FIG. 8 is a drawing of reference information device location data 141₁ through 141₆ stored in a reference information device location data storing unit 140 shown in FIG. 1;

FIG. 9A, FIG. 9B, and FIG. 9C are schematic diagrams of reference information device location data 141₁, 141₃, and 141₂, respectively;

FIG. 10 is a drawing of the result of combining the reference information device location data 141₁ shown in FIG. 9A and the reference information device location data 141₃ shown in FIG. 9B;

FIG. 11 is a drawing of the result of combining a spatial location information 151 shown in FIG. 10 and the reference information device location data 141₂ shown in FIG. 9C;

FIG. 12 is a drawing of a final form of the spatial location information 151 shown in FIG. 11;

FIG. 13 is a drawing of a distance-direction spatial location information 152 stored in a spatial location information storing unit 150 shown in FIG. 1;

FIG. 14 is a drawing of a coordinate spatial location information 153 stored in the spatial location information storing unit 150;

FIG. 15 is a drawing of a matching information 161 stored in a matching information storing unit 160 shown in FIG. 1;

FIG. 16 is a flow chart of operations of a layout survey system according to the first embodiment of the present invention;

FIG. 17 is a flow chart of a distance calculation process shown in FIG. 16;

FIG. 18 is a flow chart of a spatial location information creation process shown in FIG. 16;

FIG. 19 is a flow chart of a matching process shown in FIG. 16 and FIG. 33;

FIG. 20 is a block diagram of a layout survey apparatus according to a second embodiment of the present invention;

FIG. 21 is a drawing of an office layout that indicates the positions of information devices 400₁ through 400₆ shown in FIG. 20;

FIG. 22 is a drawing of a reference information device location data 411₃ created by a reference information device location data creating unit 402 shown in FIG. 20;

FIG. 23 is a schematic diagram of the reference information device location data 411₃;

FIG. 24 is a drawing of the reference information device location data 411₁ through 411₆ stored in a reference information device location data storing unit 410 shown in FIG. 20;

FIG. 25 is a drawing of a reference information device location data 411₅ collected from the information device 400₅ shown in FIG. 20;

FIG. 26 is a schematic diagram of the reference information device location data 411₅;

FIG. 27 is a drawing of the result of combining the reference information device location data 411₃ shown in FIG. 23 and the reference information device location data 411₅ shown in FIG. 26;

FIG. 28A and FIG. 28B are drawings of the result of combining a spatial location information 421 shown in FIG. 27 and an reference information device location data 411₂;

FIG. 29 is a drawing of a final form of the spatial location information 421 shown in FIG. 28A;

FIG. 30 is a drawing of a distance-direction spatial location information 422 stored in a spatial location information storing unit 420 shown in FIG. 20;

FIG. 31 is a drawing of a coordinate spatial location information 423 stored in the spatial location information storing unit 420 shown in FIG. 20;

FIG. 32 is a drawing of a matching information 431 stored in a matching information storing unit 430 shown in FIG. 20;

FIG. 33 is a flow chart of operations of the layout survey system according to the second embodiment of the present invention;

FIG. 34 is a flow chart of a distance calculation process shown in FIG. 33;

FIG. 35 is a flow chart of a direction calculation process shown in FIG. 33;

FIG. 36 is a flow chart of a spatial location information creation process shown in FIG. 33;

FIG. 37 is a block diagram for explaining a modification of the layout survey apparatus according to the first embodiment and the second embodiment of the present invention;

FIG. 38 is a drawing for explaining another modification of the layout survey apparatus according to the first embodiment and the second embodiment of the present invention;

FIG. 39 is a drawing of a conventional IP address/information device correspondence table 10;

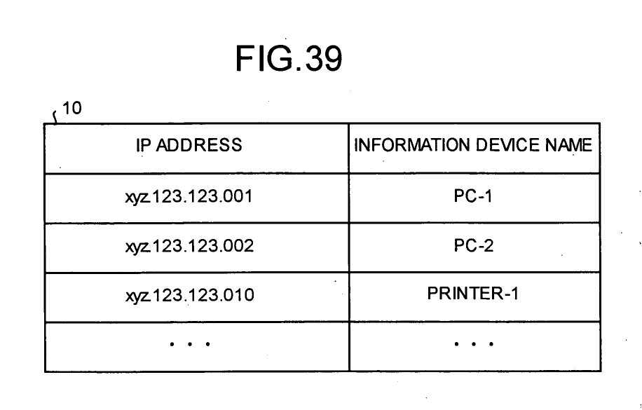

FIG. 40 is a conventional network configuration diagram 20; and

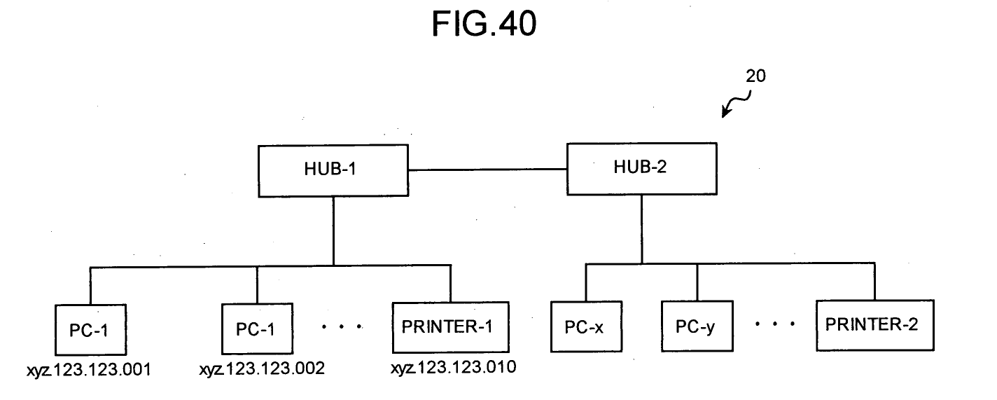

FIG. 41 is a drawing of a conventional office layout 40.

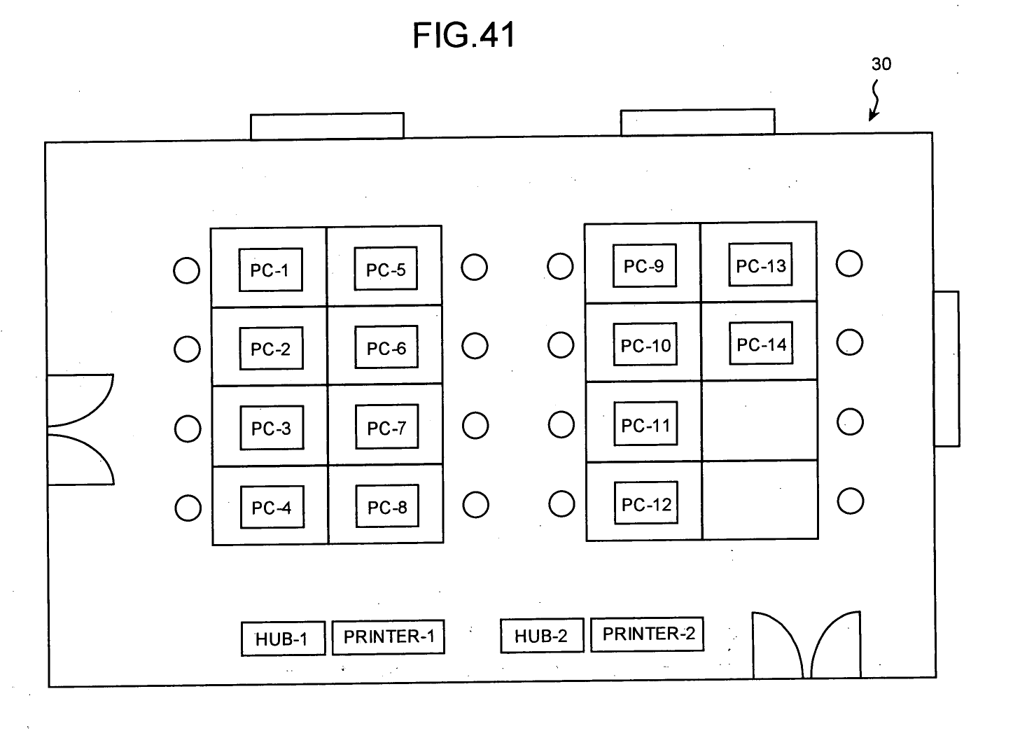

### DETAILED DESCRIPTION

Exemplary embodiments of the present invention are explained next with reference to the accompanying drawings.

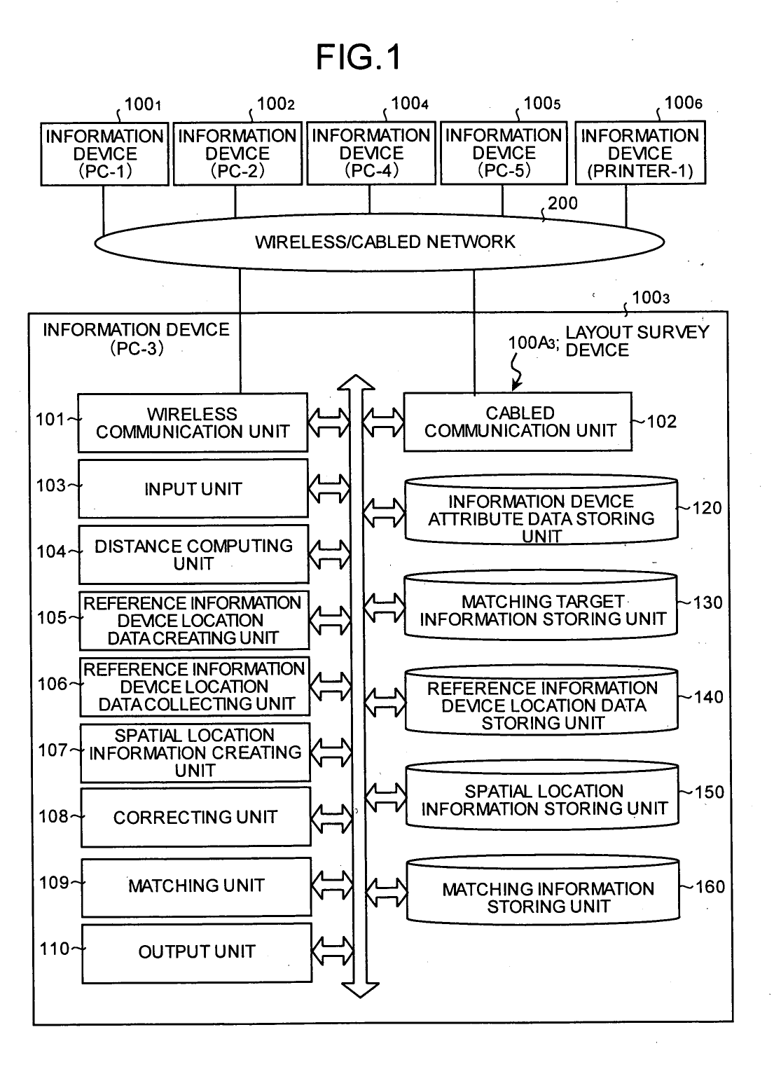

FIG. 1 is a block diagram of a layout survey apparatus according to a first embodiment of the present invention.

The layout survey system shown in FIG. 1 is for surveying the layout (spatial location) of survey object (information devices 100₁ through 100₆). In the layout survey system, the layout of the information devices 100₁ through 100₆ are surveyed on the basis of mutual distances between the information devices 100₁ through 100₆. The mutual distances between the information devices 100₁ through 100₆ are calculated on the basis of reception field intensity.

The information devices 100₁ through 100₆ are devices such as desktop PCs, notebook PCs, printers, etc. and are connected to each other via a wireless/cabled network 200. The wireless/cabled network 200 can be a wireless LAN and a cabled LAN, etc.

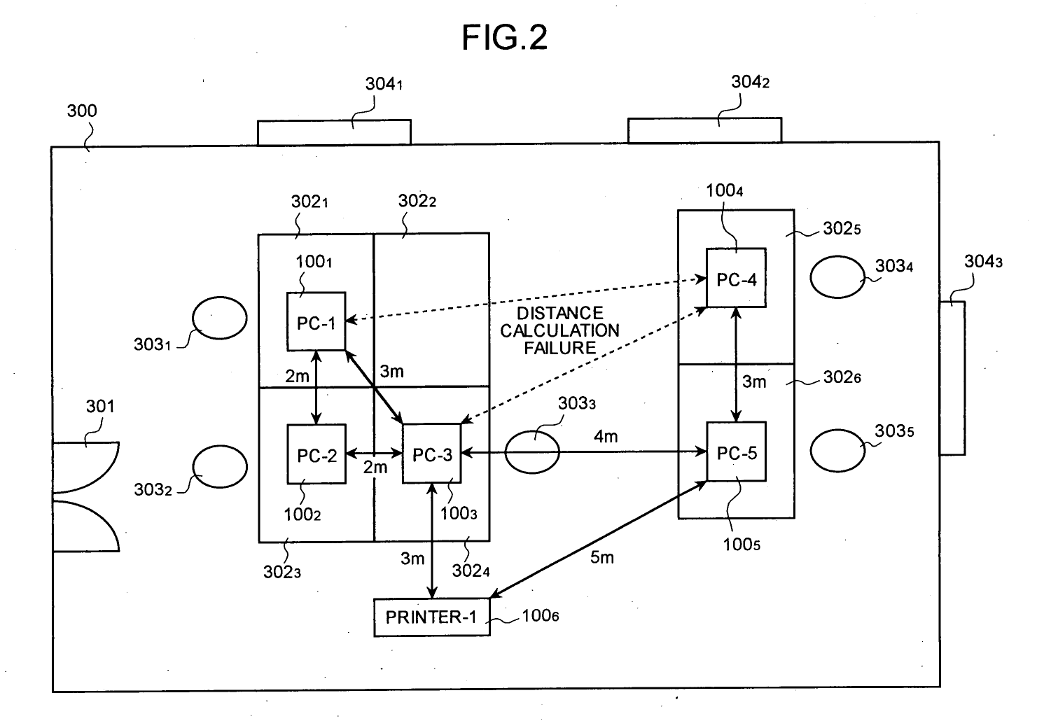

FIG. 2 is a drawing of an office layout that indicates the positions of the information devices 100₁ through 100₆ shown in FIG. 1. The information devices 100₁ through 100₆ are located on an office floor 300 and are survey objects. The office floor 300 has an entrance 301, desks 302₁ through 302₆, chairs 303₁ through 303₅, and windows 304₁ through 304₃.

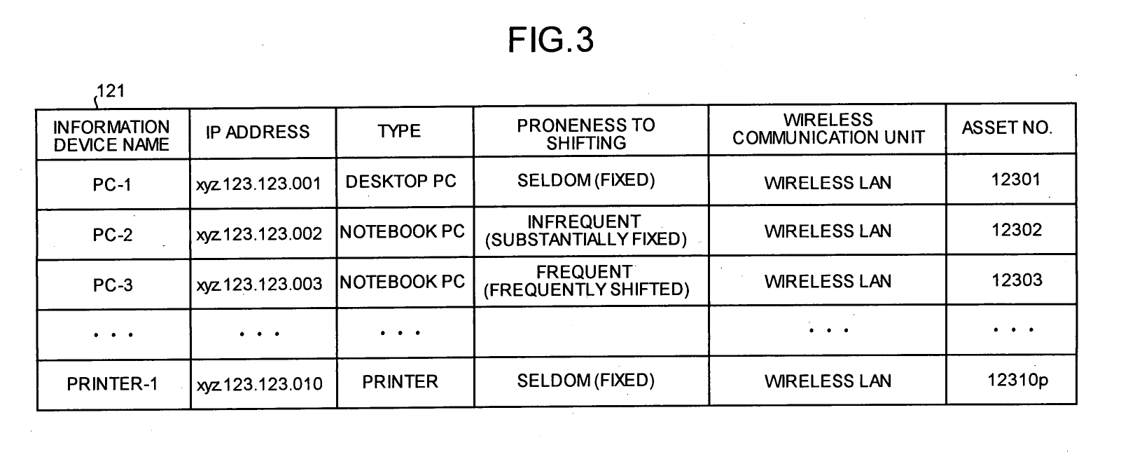

The information device 100₁ is a desktop PC (see FIG. 3) and is set on the desk 302₁. The information device name assigned to the information device 100₁ is “PC-1”. The information device 100₂ is a notebook PC and is set on the desk 302₃. The information device name assigned to the information device 100₂ is “PC-2”.

The information device 100₃ is again a notebook PC and is set on the desk 302₄. The information device name assigned to the information device 100₃ is “PC-3”. The information device 100₄ is a desktop PC and is set on the desk 302₅. The information device name assigned to the information device 100₄ is “PC-4”.

The information device 100₅ is again a desktop PC and is set on the desk 302₆. The information device name assigned to the information device 100₅ is “PC-5”. The information device 100₆ is a printer and is set on a surface close to the desk 302₄. The information device name assigned to the information device 100₆ is “Printer-1”.

To return to FIG. 1, the information device 100₃ also includes a layout survey device 100A₃ apart from a unit that realizes the functions of a PC. The layout survey device 100A₃ is provided with the function of surveying the layout of the information devices 100₁ through 100₆. Each of the other information devices 100₁, 100₂, and 1004 through 100₆ also are provided with a not shown layout survey device similar to the layout survey device 100A₃.

The layout survey devices of the information devices 100₁ through 100₆ have a master-slave relationship among them. For instance, the layout survey device 100A₃ provided in the information device 100₃ is the master, and the not shown layout survey devices of the other information devices are slaves.

The layout survey device 100A₃ of the information device 100₃ includes a wireless communication unit 101. The wireless communication unit 101 includes a wireless LAN interface, and controls wireless communication between the information devices 100₁ through 100₆ via the wireless/cabled network 200 (wireless network in this case).

The wireless communication systems that can be adapted to the wireless communication unit 101 are listed below. In the description that follows it is assumed that the wireless communication unit 101 implements the wireless LAN method.
Wireless LAN method—This is a part of the Ethernet standards and complies with the standards (such as IEEE.802.11b, etc.) set by the Institute of Electrical and Electronic Engineers (IEEE).
Bluetooth—This is a short-range wireless communication system that operates in the 2.4 GHz band and was developed as an interface for realizing data exchange between PC, peripheral devices, household, digital consumer electronics, mobile phones, etc. Mainly, its potential for use in offices is envisioned.
Home RF—This is short-range wireless communication system that operates within the 2.4 GHz band that connects PC, household goods, mobile phones, etc., and is used within homes.
Other wireless communication systems

The wireless communication systems mentioned above presume that the usage is one of short-range, and therefore the effective wireless coverage range is restricted (for instance, Bluetooth works even if there are obstructions as long as the distance between the information devices is within 10 m).

A cabled communication unit 102 includes a cabled LAN interface, and controls the cabled communication between the information devices 100₁ through 100₆ via the wireless/cabled network 200 (cabled network, in this case).

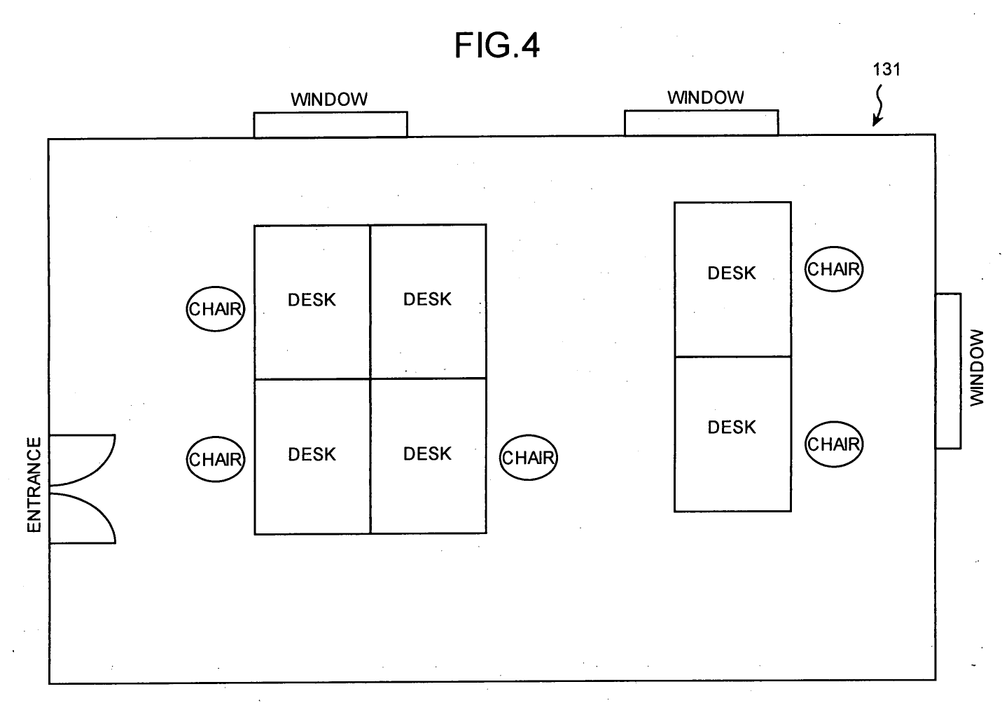

An input unit 103 is a drive device that reads information from a keyboard, mouse, or a recording medium and is used when inputting various types of information such as an information device attribute data 121 (see FIG. 3) or a matching target information 131 (see FIG. 4).

The information device attribute data 121 shown in FIG. 3 is stored in an information device attribute data storing unit (see FIG. 1) and is information pertaining to attributes of the information devices 100₁ through 100₆, which are the layout survey objects. The information device attribute data 121 includes the fields “Information device name”, “IP address”, “Type”, “Proneness to shifting”, “Wireless communication unit”, and “Asset No.”.

The field “Information device name” indicates the information device name assigned to each of the information devices 100₁ through 100₆. That is, the data that will be entered in the field “Information device name” will be PC-1 through PC-5 and Printer-1 that correspond to information devices 100₁ through 100₆.

The field “IP address” indicates the address assigned to the information devices 100₁ through 100₆ on the wireless/cabled network 200. The field “Type” indicates the type (either a desktop PC, or a notebook PC, or a printer) of the information devices 100₁ through 100₆. The field “Proneness to shifting” indicates the proneness of the information devices 100₁ through 100₆ to being shifted from one place to another and includes three options, namely, Fixed, Substantially fixed, Frequently shifted.

The field “Wireless communication unit” indicates the wireless interface (wireless LAN, Bluetooth, etc.) used by the wireless communication unit (the wireless communication unit 101 in the case of the information device 100₃) of the layout survey device installed in each of the information devices 100₁ through 100₆. The field “Asset No.” indicates the number assigned to each of the information devices under asset management.

Apart from the input unit 103, the information device attribute data 121 can also be obtained from other information devices 100₁, 1002, and 1004 through 100₆ via the wireless/cabled network 200.

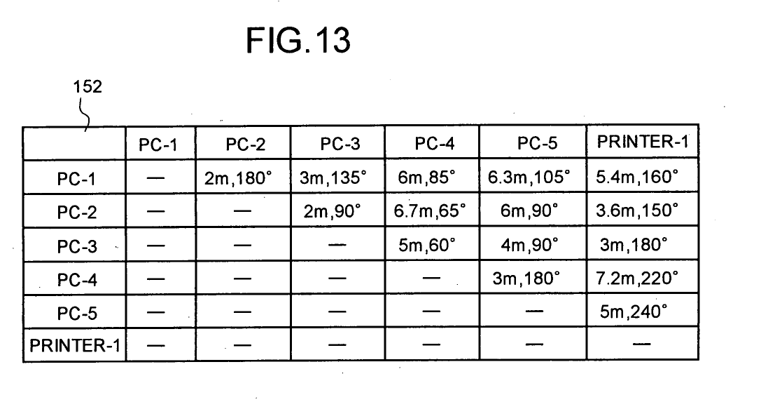

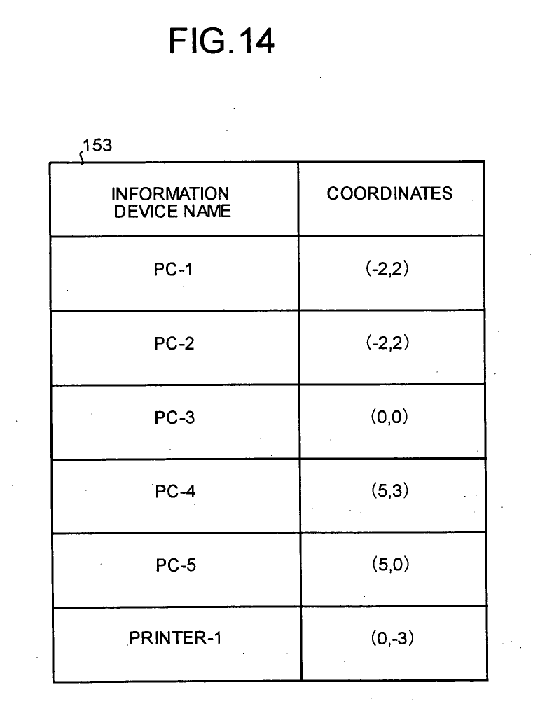

The matching target information 131 shown in FIG. 4 is information that is matched with distance-direction spatial location information 152 (see FIG. 13) or coordinate spatial location information 153 (see FIG. 14), which are described later. The matching target information 131 is information in the form of a layout drawing of all the objects shown in FIG. 2 other than the information devices 100₁ through 100₆ (namely, the office floor 300, the entrance 301, the desks 302₁ through 302₆, the chairs 303₁ through 303₅, the windows 304₁ through 304₃).

The matching target information 131 is stored in a matching target information storing unit 130 shown FIG. 1. Apart from the matching target information 131, the matching target information storing unit 130 also stores the following types of information.
Architectural plan of the building or room where the information devices are located
Block diagram of the information devices network
Asset management information database of the information devices

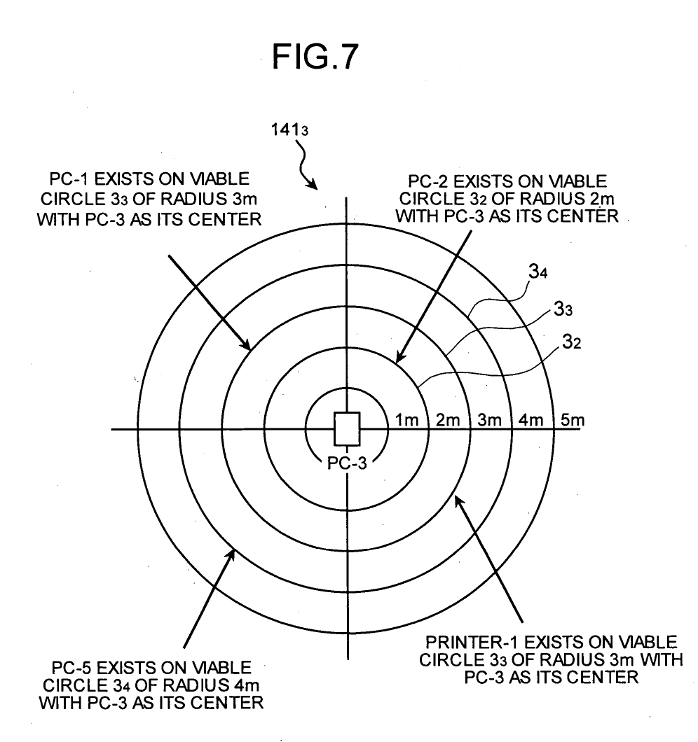

The layout survey device 100A₃ of the information device 100₃ shown in FIG. 1 possess a function for surveying the layout (see FIG. 7) of the other information devices with respect to its own information device (the information device 100₃) on the basis of the distance between itself and each of the information devices.

Each of the not shown layout survey devices of the other information devices 100₁, 100₂, and 100₄ through 100₆ also possesses the function of surveying the layout of the other information devices with respect to its own information device on the basis of the distance between itself and each of the information devices.

The layout survey device 100A₃ of the information device 100₃ also possesses the function of integrating the survey result of the information device 100₃ and the survey result of each of the other information devices 100₁, 100₂, and 100₄ through 100₆.

A distance computing unit 104 computes, on the basis of the reception field intensity, the distance between itself (the information device 100₃ in this case) and each of the other information devices 100₁, 100₂, and 100₄ through 100₆ on the basis of the information device attribute data 121 (see FIG. 3).

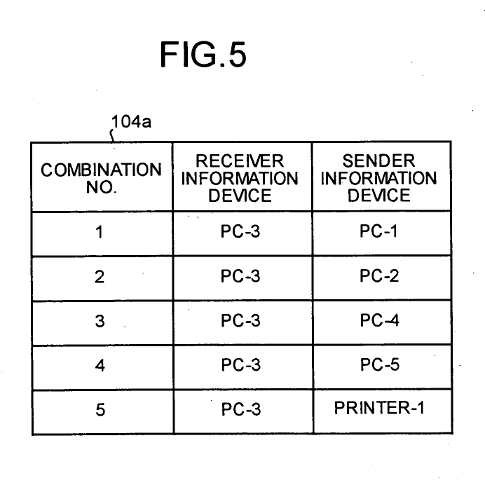

To be specific, the distance computing unit 104 creates an information device combination table 104a shown in FIG. 5 by combining itself (in this case PC-3 (the information device 100₃)) with each of PC-1, PC-2, PC-4, PC-5, and Printer-1 (that is, the information devices 100₁, 100₂, and 100₄ through 1006).

In the information device combination table 104a, the column “Sender information device” indicates the information device that sends radio waves to a receiver information device, and includes PC-1 (the information device 100₁), PC-2 (the information device 100₂), PC-4 (the information device 100₄), PC-5 (the information device 100₅), and Printer-1 (the information device 100₆).

The column “Receiver information device” indicates the information device that receives the radio waves from the sender information device, and in the information device combination table 104a, the receiver information device is PC-3 (information device 100₃).

The distance computing unit 104 measures the reception field intensity when communication is established between the wireless communication units of each pair of information devices in the information device combination table 104a. The distance computing unit 104 then calculates the distance between the information devices on the basis of the reception field intensity.

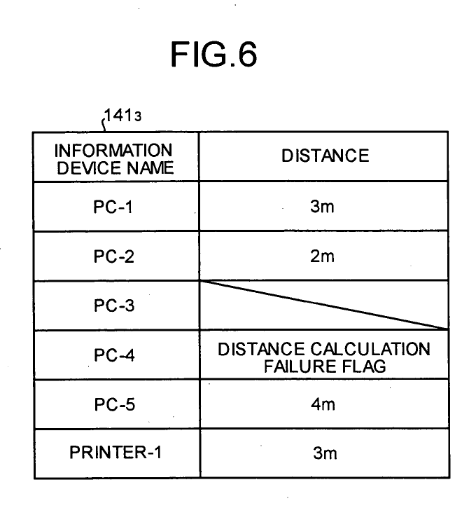

However, the distance between the information devices cannot be calculated in the following cases. Hence, in these cases a distance calculation failure flag (see FIG. 6), which is described later, is set.
When the distance between two information devices exceeds the effective wireless coverage range
When there is an obstruction between two information devices, preventing radio waves from reaching the information device
When the wireless communication units of the two information devices have different wireless systems—that is, if the wireless system of one communication unit is wireless LAN that complies with Ethernet and the wireless system of the other communication unit is Bluetooth.

To return to FIG. 1, a reference information device location data creating unit 105 creates reference information device location data 141₃ (see FIG. 6), on the basis of the calculation result of the distance computing unit 104. The reference information device location data 141₃ indicates where the other information devices are located with respect to the information device 100₃ (PC-3) shown in FIG. 2 considering PC-3 as the reference information device.

The reference information device location data 141₃ shown in FIG. 6 is information that indicates the distance of each of the other information devices from PC-3 (the reference information device). In the example shown in FIG. 6, PC-1 is at a distance of 3 m from PC-3 (the reference information device). However, the direction of PC-1 from PC-3 is unknown. Further, the distance between PC-3 (the reference information device) and PC-4 is not calculable (that is, a distance calculation failure flag is set).

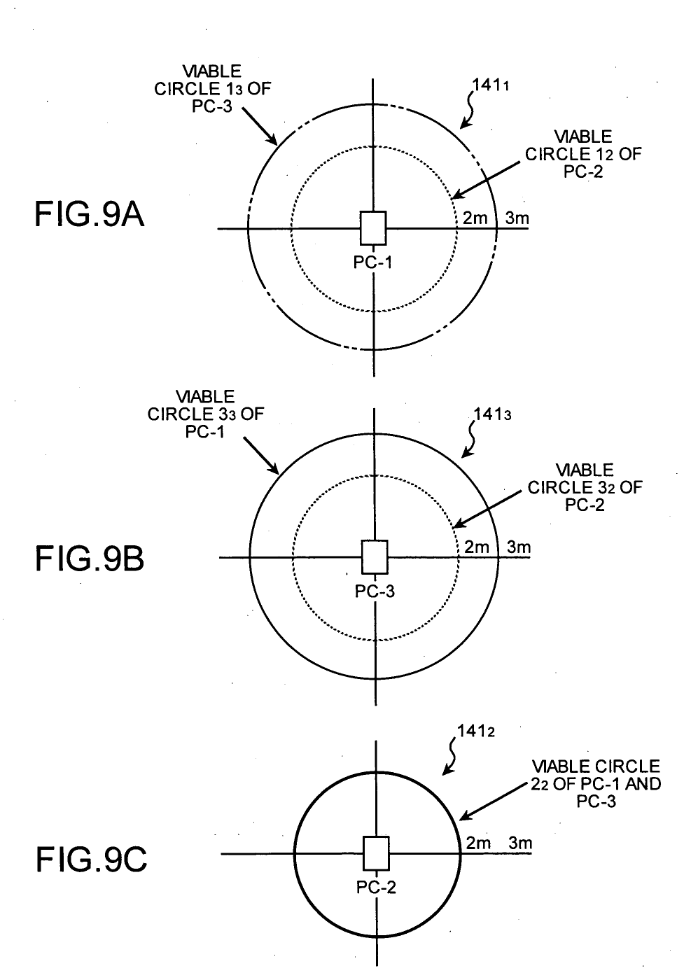

FIG. 7 is a schematic diagram of the reference information device location data 141₃. In FIG. 7, concentric circles of radii in units of 1 m and corresponding to the distances shown in FIG. 6 are shown, with the reference information device (PC-3) representing the center. FIG. 9B shows an abridged version (showing only viable circles 3₃ and 3₂) of the reference information device location data 141₃ shown in FIG. 7.

In. FIG. 7, PC-1 exists on the viable circle 3₃ of a radius of 3 m (Distance 3 m—see FIG. 6) with PC-3 as its center. PC-2 exists on the viable circle 3₂ of a radius of 2 m (Distance 2 m—see FIG. 6) with PC-3 as its center.

PC-5 exists on a viable circle 3₄ of a radius of 4 m (Distance 4 m—see FIG. 6) with PC-3 as its center. Printer-1 exists on the viable circle 3₃ of a radius of 3 m (Distance 3 m—see FIG. 6) with PC-3 as its center.

The reference information device location data 141₃ created by the reference information device location data creating unit 105 of the information device 100₃ (PC-3) is stored in a reference information device location data storing unit 140 (see FIG. 1).

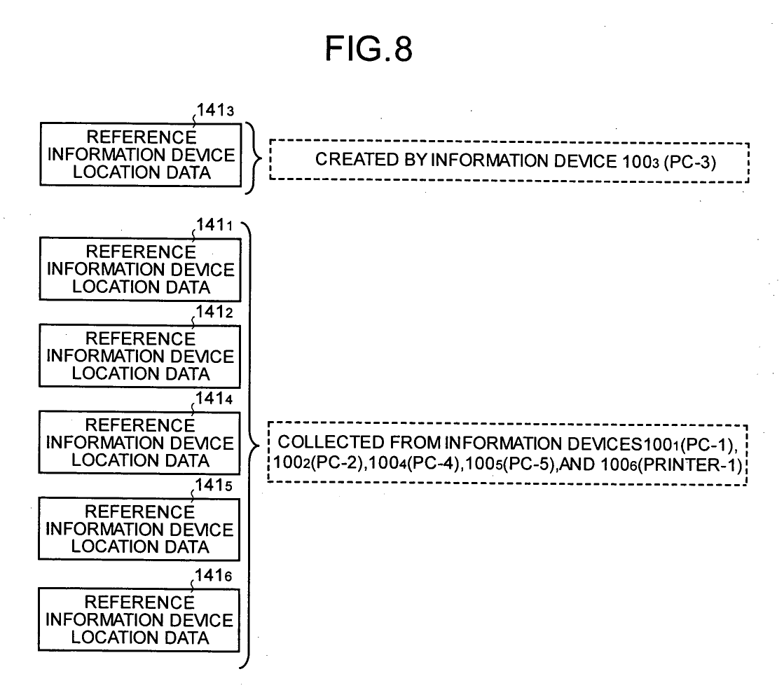

The not shown respective layout survey devices of the information device 100₁ (PC-1), the information device 100₂ (PC-2), the information device 100₄ (PC-4), the information device 100₅ (PC-5), and the information device 100₆ (Printer-1) also create, by taking their own information device as the reference information device, reference information device location data 141₁, 141₂, 141₄, 141₅, and 141₆ (see FIG. 8).

For instance, as shown in FIG. 9A, the not shown layout survey device of the information device 100₁ (PC-1) creates the reference information device location data 141₁ by taking PC-1 as the reference information device.

In the reference information device location data 141₁, PC-2 (the information device 100₂) exists on a viable circle 1₂ of a radius of 2 m (Distance 2 m—see FIG. 2) with PC-1 as its center. PC-3 (the information device 100₃) exists on a viable circle 1₃ of a radius of 3 m (Distance 3 m—see FIG. 2) with PC-1 as its center.

Further, as shown in FIG. 9C, the not shown layout survey device of the information device 100₂ (PC-2) creates the reference information device location data 141₂ by taking PC-2 as the reference information device.

In the reference information device location data 141₂, PC-1 (the information device 100₁) exists on a viable circle 2₂ of a radius of 2 m (Distance 2 m—see FIG. 2) with PC-2 as its center. PC-3 (information device 100₃) also exists on the same viable circle 2₂.

To return to FIG. 1, a reference information device location data collecting unit 106 collects, via the cabled communication unit 102 (the wireless communication unit 101 can also be used) the reference information device location data 141₁, 141₂, 141₄, 141₅, and 141₆ from the layout survey devices of the information device 100₁ (PC-1), 100₂ (PC-2), 100₄ (PC-4), 100₅ (PC-5), and 100₆ (Printer-1) respectively, and stores the collected data in the reference information device location data storing unit 140 (see FIG. 1). In the first embodiment, the reference information device location data collecting unit 106 can store the reference information device location data in the reference information device location data storing unit 140 by correlating it to the time at which the data is created.

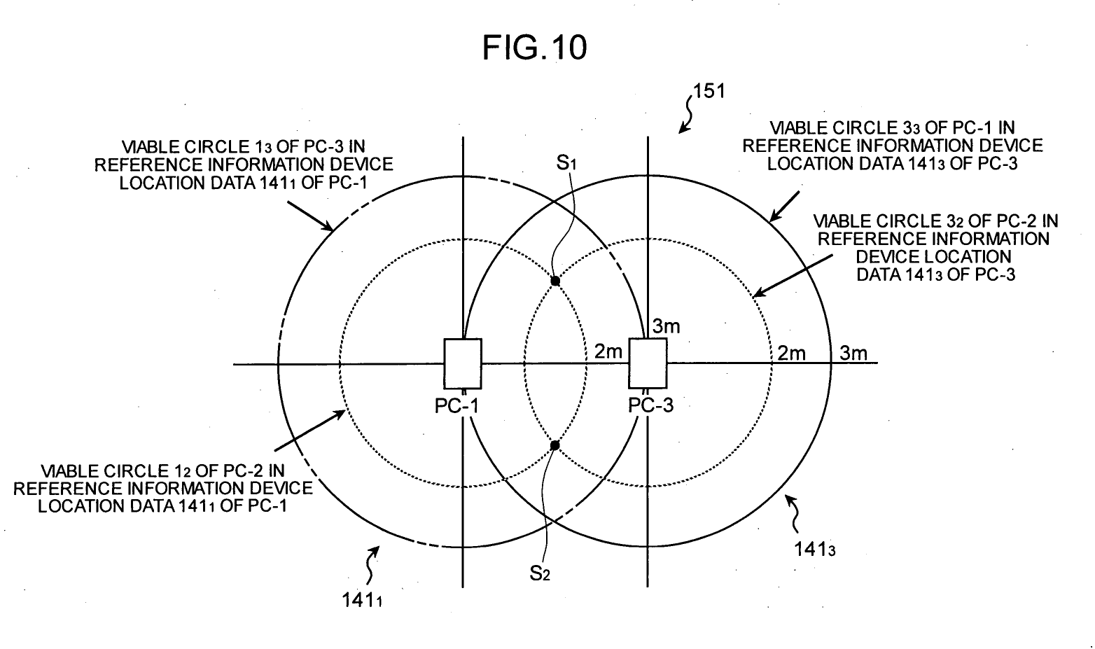

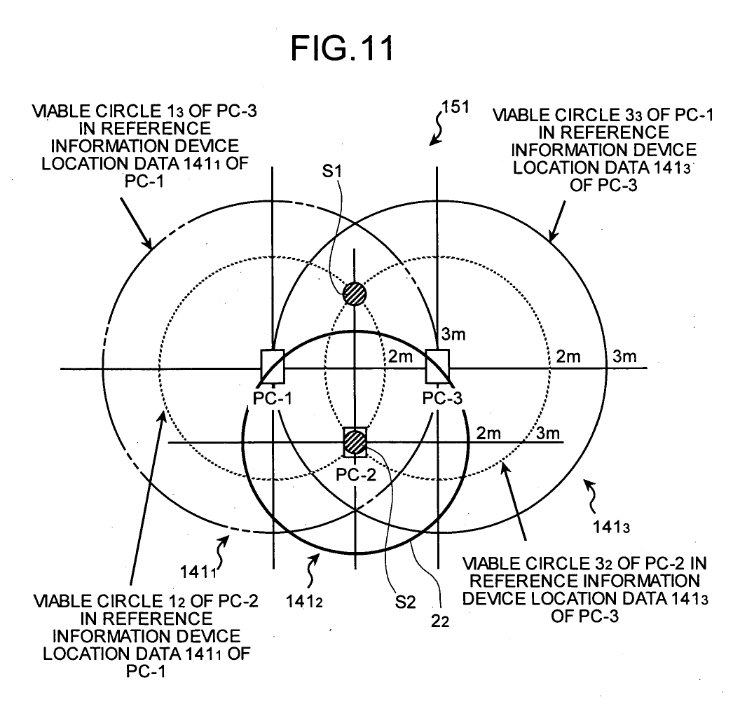

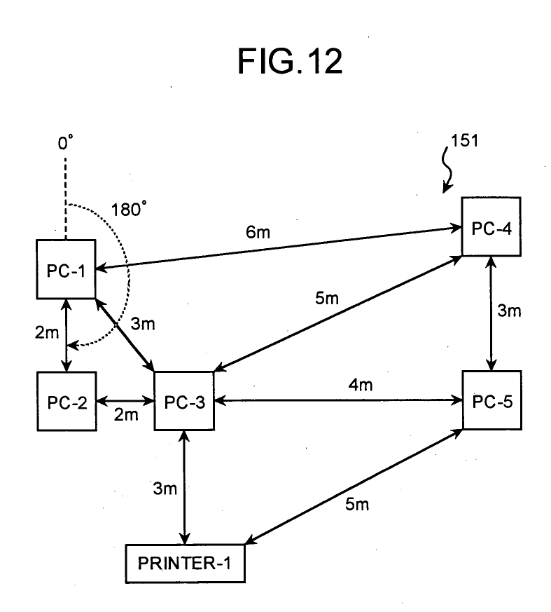

A spatial location information creating unit 107 creates a spatial location information 151 shown in FIG. 12 by sequentially combining the reference information device location data 141₁, through 141₆ stored in the reference information device location data storing unit 140, as shown in FIG. 10 and FIG. 11. The spatial location information 151 is information that indicates the spatial location (layout) of each of the information devices being surveyed, and is a survey result of the layout survey device 100A₃.

The spatial location information creating unit 107 creates from the spatial location information 151, either the distance-direction spatial location information 152 (see FIG. 13) or the coordinate spatial location information 153 (see FIG. 14), and stores the distance-direction spatial location information 152 and the coordinate spatial location information 153 in a spatial location information storing unit 150 (see FIG. 1).

A correcting unit 108 is provided with a function of correcting the distance-direction spatial location information 152 or the coordinate spatial location information 153 stored in the spatial location information storing unit 150. To be specific, the correcting unit 108 performs correction either manually or automatically, as described below.

(A) Manual Correction
Correcting by specifying recalculation of the entire spatial location information
Manually correcting a part of the spatial location information

(B) Automatic Correction

Automatic correction is carried out when there is a change in the distance or direction between the information devices.

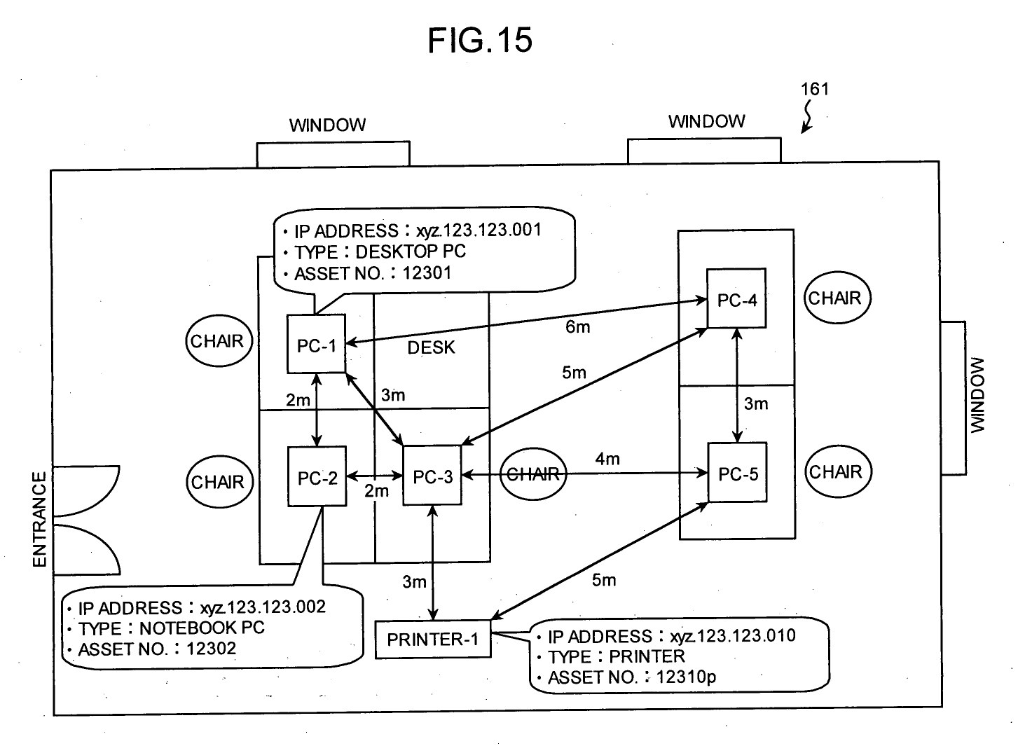

A matching unit 109 creates a matching information 161 shown in FIG. 15 by matching the matching target information (for instance, the matching target information 131—see FIG. 4) stored in the matching target information storing unit 130 and the spatial location information (for instance, the distance-direction spatial location information 152—see FIG. 13) stored in the spatial location information storing unit 150, and stores the matching information 161 in a matching information storing unit 160 (see FIG. 1).

An output unit 110 outputs the spatial location information 151 (see FIG. 12), the distance-direction spatial location information 152 (see FIG. 13), the coordinate spatial location information (see FIG. 14), and the matching information 161 (see FIG. 15).

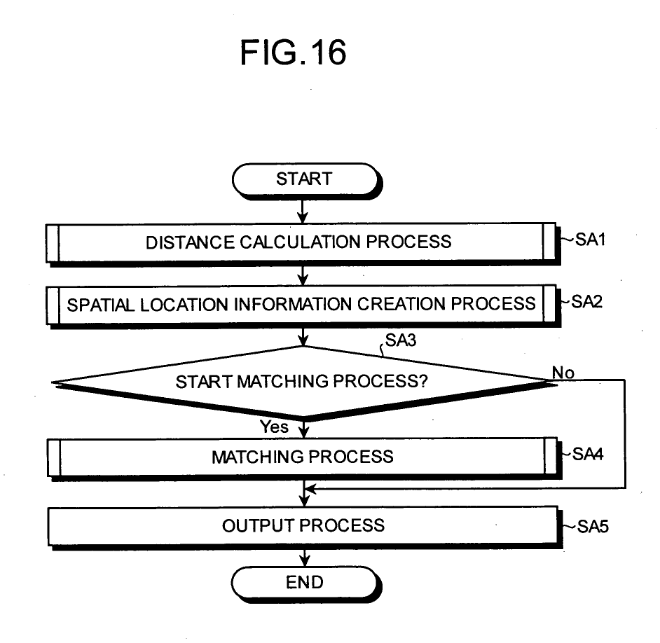

The operation of the layout survey system according to the first embodiment is explained next with reference to the flow charts shown in FIG. 16 through FIG. 19. The layout survey system in this example is shown to survey the layout (spatial locations) of the information devices 100₁ through 100₆ shown in FIG. 2.

In Step SA1 shown in FIG. 16, the layout survey system carries out a distance calculation process. The distance calculation process involves calculating the distance between the information device 100₃ (PC-3) and each of the other information devices 100₁, 100₂, and 100₄ through 100₆ shown in FIG. 1.

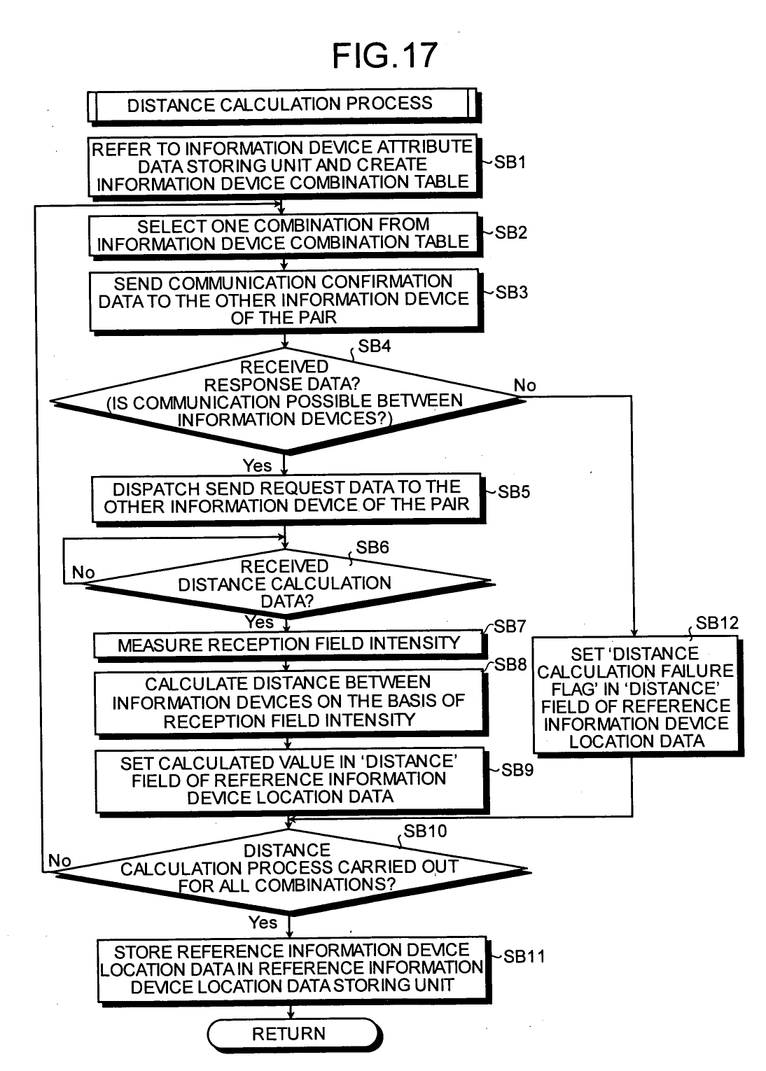

The distance calculation process is explained next. FIG. 17 is a flow chart of the distance calculation process. In Step SB1, the distance computing unit 104 refers to the information device attribute data storing unit 120, and creates the information device combination table 104a shown in FIG. 5 from the information device attribute data 121 (see FIG. 3).

In Step SB2, the distance computing unit 104 selects one of the combinations from the information device combination table 104a. Let us assume that the distance computing unit 104 selects the combination with a Combination No. “1”, in which a Receiver information device is “PC-3” and a Sender information device is “PC-1”.

In Step SB3, the distance computing unit 104 sends a communication confirmation data to the other information device of the pair, that is, the sender information device PC-1 (the information device 100₁), via the wireless communication unit 101 and the wireless/cabled network 200.

The not shown layout survey device of PC-1 (the information device 100₁) receives the communication confirmation data. In response, the layout survey device of PC-1 (the information device 100₁) sends a response data to PC-3 (the information device 100₃) via the wireless/cabled network 200. The wireless communication unit 101 receives the response data.

In Step SB4, the distance computing unit 104 determines whether the response data has been received, that is, whether communication is possible between the communication devices (PC-3 and PC-1, in this case).

If the answer in Step SB4 is “Yes”, the distance calculation process proceeds to Step SB5. In Step SB5, the distance computing unit 104 sends a send request data, requesting for information required for distance calculation (hereinafter, “distance calculation data”), to the other information device of the pair, that is, the sender information device PC-1 (the information device 100₁), via the wireless communication unit 101 and the wireless/cabled network 200.

The not shown layout survey device of PC-1 (the information device 100₁) receives the send request data. In response, the layout survey device of PC-1 (the information device 1001) sends the distance calculation data to PC-3 (the information device 100₃) via the wireless/cabled network 200.

In Step SB6, the distance computing unit 104 determines whether the distance calculation data has been received by the wireless communication unit 101. If the answer in Step SB6 is “No”, the distance computing unit 104 repeats Step SB6.

If the answer in Step SB6 is “Yes”, the distance calculation process proceeds to Step SB7. In Step SB7, the distance computing unit 104 measures the reception field intensity of the distance calculation data. In Step SB8, the distance computing unit 104 calculates using a known expression and on the basis of the reception field intensity, the distance, say 3 m (see FIG. 2), between the two information devices (PC-3 and PC-1, in this case).

In Step SB9, the reference information device location data creating unit 105 sets “3 m” in the “Distance” field (corresponding to PC-1, in this case) of the reference information device location data 141₃ shown in FIG. 6.

In Step SB10, the distance computing unit 104 determines whether the distance calculation process has been carried out for all the combinations in the information device combination table 104a shown in FIG. 5.

If the answer in Step SB10 is “No”, the distance calculation process goes back to Step SB2. In Step SB2, the distance computing unit 104 selects the combination with the Combination No. “2”, in which the Receiver information device is “PC-3” and the Sender information device is “PC-2”. The subsequent Steps SB3 through SB8 are the same as described earlier. In Step SB9, the reference information device location data creating unit 105 sets “2 m” calculated in Step SB8 in the “Distance” field (corresponding to PC-2, in this case) of the reference information device location data 141₃ shown in FIG. 6.

If the answer in Step SB10 is “No”, in Step SB2, the distance computing unit 104 selects from the information device combination table 104a that combination with the Combination No. “3”, in which the Receiver information device is “PC-3” and the Sender information device is “PC-4”.

In Step SB3, the distance computing unit 104 sends a communication confirmation data to the other information device of the pair, that is, the sender information device PC-4 (the information device 100₄), via the wireless communication unit 101 and the wireless/cabled network 200.

If wireless communication is not possible between PC-3 and PC-4, the not shown layout survey device of PC-4 (the information device 100₄) cannot receive the communication confirmation data. Hence, in this case, the layout survey device of PC-4 will not be able to send a response data.

Since no response data is received from PC-4, that is, since no communication is possible between the information devices (PC-3 and PC-4, in this case), the answer in Step SB4 is “No”.

The distance calculation process proceeds to Step SB12. In Step SB12, the reference information device location data creating unit 105 sets “Distance calculation failure flag” in the “Distance” field (corresponding to PC-4, in this case) of the reference information device location data 141₃ shown in FIG. 6.

If the answer in Step SB10 is “No”, Steps SB2 through SB10 are repeated for Combination No. “4” and Combination No. “5” in the information device combination table 104a shown in FIG. 5.

If the answer in Step SB10 is “Yes”, the distance calculation process proceeds to Step SB11. In Step SB11, the reference information device location data creating unit 105 stores the reference information device location data 141₃ shown in FIG. 6 in the reference information device location data storing unit 140. The distance calculation process ends here.

The layout survey devices of the other information devices, namely PC-1 (the information device 100₁), PC-2 (the information device 100₂), PC-4 (the information device 100₄), PC-5 (the information device 100₅), and Printer-1 (the information device 100₆) similarly carry out the distance calculation process, and respectively create and store the reference information device location data 141₁, 141₂, 141₄, 141₅, and 141₆ (see FIG. 8) created by taking respective information device as the reference information device.

To return to FIG. 16, in Step SA2, the layout survey system carries out a spatial location information creation process to create the spatial location information (the spatial location information 151 (see FIG. 12), the distance-direction spatial location information 152 (see FIG. 13), and the coordinate spatial location information 153 (see FIG. 14)) that indicates the spatial locations (layout) of the information devices 100₁ through 100₆ shown in FIG. 2.

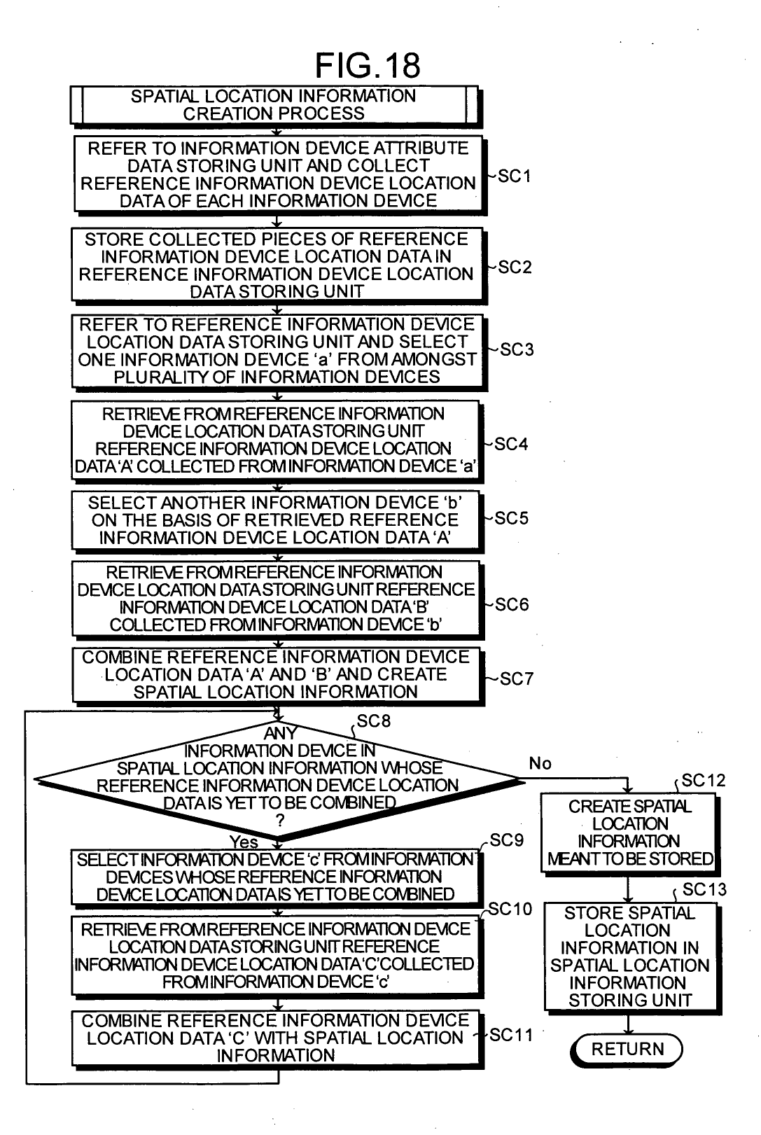

The spatial location information creation process is described next. FIG. 18 is a flow chart of the spatial location information creation process. In Step SC1, the reference information device location data collecting unit 106 refers to the information device attribute data 121 shown in FIG. 3, and collects from all the information devices except PC-3 (the information device 100₃), that is, from PC-1 (the information device 100₁), PC-2 (the information device 100₂), PC-4 (the information device 100₄), PC-5 (the information device 100₅), and Printer-1 (the information device 100₆), the respective reference information device location data 141₁, 141₂, 141₄, 141₅, and 141₆ (see FIG. 8) via the wireless/cabled network 200.

In Step SC2, the reference information device location data collecting unit 106 stores the collected reference information device location data 141₁, 141₂, 141₄, 141₅, and 141₆ in the reference information device location data storing unit 140.

In Step SC3, the spatial location information creating unit 107 refers to the information device attribute data storing unit 120, and selects one information device (hereinafter, “information device a”), for instance PC-1 (the information device 100₁) out of a plurality of information devices. The criterion for selecting the information device a is that the information device (reference information device) should have the most number of distances calculated between itself and the other information devices.

In Step SC4, the spatial location information creating unit 107 retrieves from the reference information device location data storing unit 140 the reference information device location data (hereinafter, “reference information device location data A”) collected from the information device a.

In this case, the spatial location information creating unit 107 retrieves from the reference information device location data storing unit 140 the reference information device location data 141₁, shown in FIG. 9A, collected from PC-1 (the information device 100₁).

In Step SC5, the spatial location information creating unit 107 selects one information device (hereinafter, “information device b”) on the basis of the retrieved reference information device location data A.

In this case, the spatial location information creating unit 107 selects as the information device b, PC-3 (the information device 100₃) that exists on the viable circle 1₃ in the reference information device location data 141₁ shown in FIG. 9A.

In Step SC6, the spatial location information creating unit 107 retrieves from the reference information device location data storing unit 140, the reference information device location data (hereinafter, “reference information device location data B”) collected from the information device b.

In this case, the spatial location information creating unit 107 retrieves from the reference information device location data storing unit 140, the reference information device location data 141₃, shown in FIG. 9B, collected from PC-3 (the information device 100₃).

In Step SC7, the spatial location information creating unit 107 combines the reference information device location data A retrieved in Step SC4 and the reference information device location data B retrieved in Step SC6, and creates the spatial location information.

To be specific, the spatial location information creating unit 107 combines the reference information device location data 141₁ (see FIG. 9A) and the reference information device location data 141₃ (see FIG. 9B) and creates the spatial location information 151, as shown in FIG. 10.

In this case, the spatial location information creating unit 107 combines the reference information device location data 141₁ and the reference information device location data 141₃ in such a way that PC-1 (reference information device) of the reference information device location data 141₁ is located on the viable circle 3₃ of the reference information device location data 141₃ and PC-3 (reference information device) of the reference information device location data 141₃ is located on the viable circle 1₃ of the reference information device location data 141₁.

Points of intersection S₁ and S₂ of the viable circle 1₂ of the reference information device location data 141₁ and the viable circle 3₂ of the reference information device location data 141₃ are the potential locations where PC-2 (the information device 100₂) will be located. The points of intersection and viable circles are the potential locations for placing the information devices.

To return to FIG. 18, in Step SC8, the spatial location information creating unit 107 checks whether any information device remains whose reference information device location data has not been combined yet (the first time checking is done for the spatial location information 151 shown in FIG. 10. Subsequently, checking is done for the spatial location information 151 updated in Step SC11).

In the example shown in FIG. 10, the information devices whose reference information device location data are not yet combined are PC-2 that corresponds to the viable circles 1₂ and 3₂, and Printer-1 that corresponds to the viable circle 3₃. However, as shown in FIG. 7, the reference information device location data 141₃ also includes the viable circle 3₄ corresponding to PC-5. Therefore, the information devices whose reference information device location data are yet to be combined are PC-2, Printer-1, and PC-5.

If the answer in Step SC8 is “Yes”, the spatial location information creation process proceeds to Step SC9. In Step SC9, the spatial location information creating unit 107 selects one of the information devices (hereinafter, “information device c”) that are not yet combined (PC-2, Printer-1, and PC-5).

Let us suppose that the spatial location information creating unit 107 selects PC-2 (the information device 100₂) as the information device c.

In Step SC10, the spatial location information creating unit 107 retrieves the reference information device location data (hereinafter, “reference information device location data C”) from the reference information device location data storing unit 140.

In this case, the spatial location information creating unit 107 retrieves from the reference information device location data storing unit 140 the reference information device location data 141₂ shown in FIG. 9C collected from PC-2 (the information device 100₂).

In Step SC11, the spatial location information creating unit 107 combines the reference information device location data C retrieved in Step SC10 with the spatial location information.

To be specific, the spatial location information creating unit 107 combines the reference information device location data C retrieved in Step SC10 with the latest spatial location information 151 (FIG. 10, in this case), to update the spatial location information 151 shown in FIG. 10 to the spatial location information 151 shown in FIG. 11.

In this case, the spatial location information creating unit 107 updates the spatial location information 151 shown in FIG. 10 by combining it with the reference information device location data 141₂ shown in FIG. 9C in such a way that PC-2 (reference information device) of the reference information device location data 141₂ is located on the point of intersection S₂, and PC-1 (reference information device) of the reference information device location data 141₁ and PC-3 (reference information device) of the reference information device location data 141₃ are located on the viable circle 2₂ of the reference information device location data 141₂.

When the potential location for placing an information device is two points of intersection, the reference information device of the reference information device location data is placed at either of the two points of intersection (in the case described, the information device is placed at the intersection point S₂). When the potential location for placing an information device is on a viable circle, the information device is placed anywhere on the viable circle.

To return to FIG. 18, in Step SC8, the spatial location information creating unit 107 checks whether any information device remains whose reference information device location data has not been combined yet. Since reference information device location data of PC-5 and Printer-1 still remain to be combined, the answer in Step SC8 is “Yes”.

The spatial location information creating unit 107 repeats Steps SC9 through SC11 until the answer in Step SC8 is “No”. For instance, the reference information device location data 141₅ (corresponding to PC-5) is combined with the spatial location information 151 and the spatial location information 151 is updated. Following this, the reference information device location data 141₆ (corresponding to Printer-1) is combined with the updated spatial location information 151 and the spatial location information 151 is updated again. FIG. 12 shows the finally updated spatial location information 151, and is essentially a schematic diagram of the spatial locations (layout) of the information devices being surveyed.

If the answer in Step SC8 is “No”, the spatial location information creation process proceeds to Step SC12. In Step SC12, the spatial location information creating unit 107 creates from the spatial location information 151 shown in FIG. 12 the distance-direction spatial location information 152 shown in FIG. 13 meant to be stored.

The distance-direction spatial location information 152 contains the distance and direction between each pair of information devices in the form of a matrix. For instance, as shown in FIG. 12, the distance between PC-1 and PC-2 is 2 m and the direction is 180° (that is, if the perpendicular of PC-1 is taken as a reference 0°, PC-2 is located 180° clockwise with respect to PC-1).

Alternatively, in the first embodiment, the spatial location information creating unit 107 can create from the spatial location information 151 shown in FIG. 12 the coordinate spatial location information 153 shown in FIG. 14 meant to be stored. In the coordinate spatial location information 153, the location of each of the information devices is represented by coordinates in a two-dimensional coordinate system with respect to the location of PC-3 shown in FIG. 12, whose coordinates are taken to be (0,0).

To return to FIG. 18, in Step SC13, the spatial location information creating unit 107 stores the distance-direction spatial location information 152 (see FIG. 13) or the coordinate spatial location information 153 (see FIG. 14) in the reference information device location data storing unit 140. The spatial location information creation process ends here.

To return to FIG. 16, in Step SA3, the layout survey system determines whether a matching process is to be carried out. If the answer in Step SA3 is “No”, the layout survey system proceeds to Step SA5. In Step SA5, the output unit 110 retrieves from the spatial location information storing unit 150 and outputs the distance-direction spatial location information 152 (see FIG. 13) or the coordinate spatial location information 153 (see FIG. 14).

If the answer in Step SA3 is “Yes”, the layout survey system proceeds to Step SA4. In Step SA4 the layout survey system carries out the matching process to match the matching target information and the spatial location information.

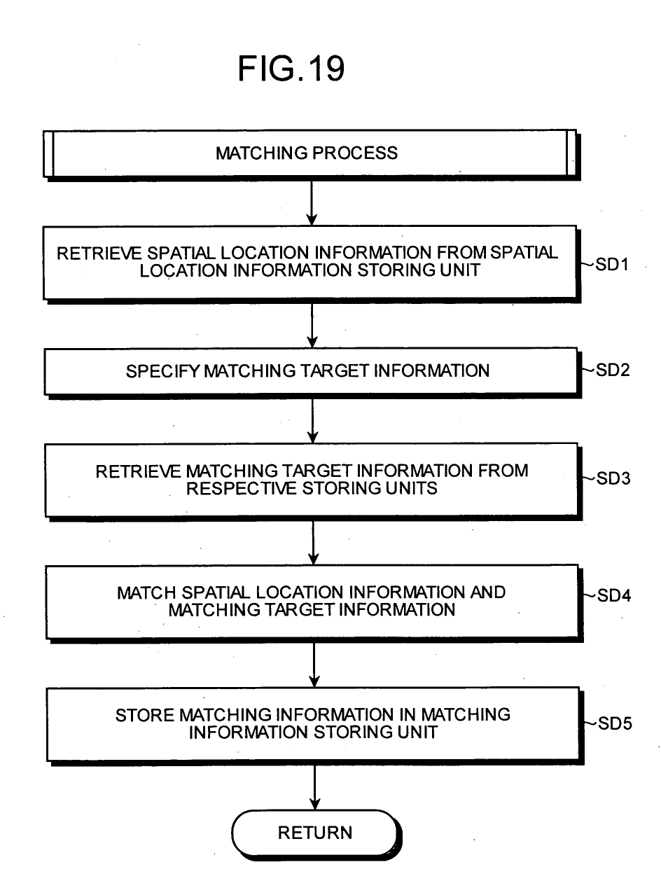

The matching process is explained next. FIG. 19 is a flow chart of the matching process. In Step SD1, the matching unit 109 retrieves the distance-direction spatial location information 152 shown in FIG. 13 or the coordinate spatial location information 153 shown in FIG. 14 from the spatial location information storing unit 150.

In Step SD2, a user can specify as the matching target information, say, the matching target information 131 (see FIG. 4) and the information device attribute data 121 (see FIG. 3) by means of the input unit 103. In Step SD3, the matching unit 109 retrieves from the respective storing units (in this case, from the matching target information storing unit 130 and the information device attribute data storing unit 120) the matching target information 131 and the information device attribute data 121 specified in Step SD2.

In Step SD4, the matching unit 109, matches the distance-direction spatial location information 152 (see FIG. 13) retrieved in Step SD1, and the matching target information 131 (see FIG. 4) as well as the information device attribute data 121 (see FIG. 3) retrieved in Step SD3, and creates the matching information 161 shown in FIG. 15.

The matching information 161 contains the information device attribute data (IP address, Type, and Asset No.) of each of the information devices (PC-1, PC-2, etc.) correlated to the respective information device.

In Step SD5, the matching unit 109 stores the matching information 161 (see FIG. 15) in the matching information storing unit 160. The matching process ends here. To return to FIG. 15, the layout survey system proceeds to Step SA5. In Step SA5, the output unit 110 retrieves from the matching information storing unit 160 and outputs the matching information 161 (see FIG. 15).

Thus, one of a plurality of survey objects (the information devices 100₁ through 100₆), the information device 100₃ in this case, is taken as the reference survey object. The distance between the reference survey object and each of the other survey objects is calculated on the basis of the reception field intensity. The reference information device location data 141₃ (see FIG. 6 and FIG. 7) that indicates the layout is created on the basis of the distances of the other survey objects from the reference survey object. Similarly, by taking each of the other survey objects as the reference survey object, the reference information device location data 141₁, 141₂, and 141₄ through 141₆ are created. The reference information device location data thus created are combined on the basis of the distances to create the spatial location information 151 etc. (see FIG. 12) that indicates the layout of the survey objects. Thus, the layout of the survey objects can be surveyed quickly and accurately.

According to the first embodiment, as shown in FIG. 15, the matching unit 109 matches associated information (such as the information device attribute data, matching target information, etc.) pertaining to the plurality of survey objects with the spatial location information. Consequently, the association between the associated information and the survey objects can be clearly defined, thereby enhancing user-friendliness.

Further, according to the first embodiment, the correcting unit 108 corrects the spatial location information. Consequently, minute adjustments can be made in the spatial location information according to the actual layout.

In the first embodiment, a structure that creates spatial location information on the basis of the distances between the survey objects is explained. The spatial location information can also be calculated on the basis of both distance and direction. In a second embodiment of the present invention, the spatial location information is calculated on the basis of both distance and the direction.

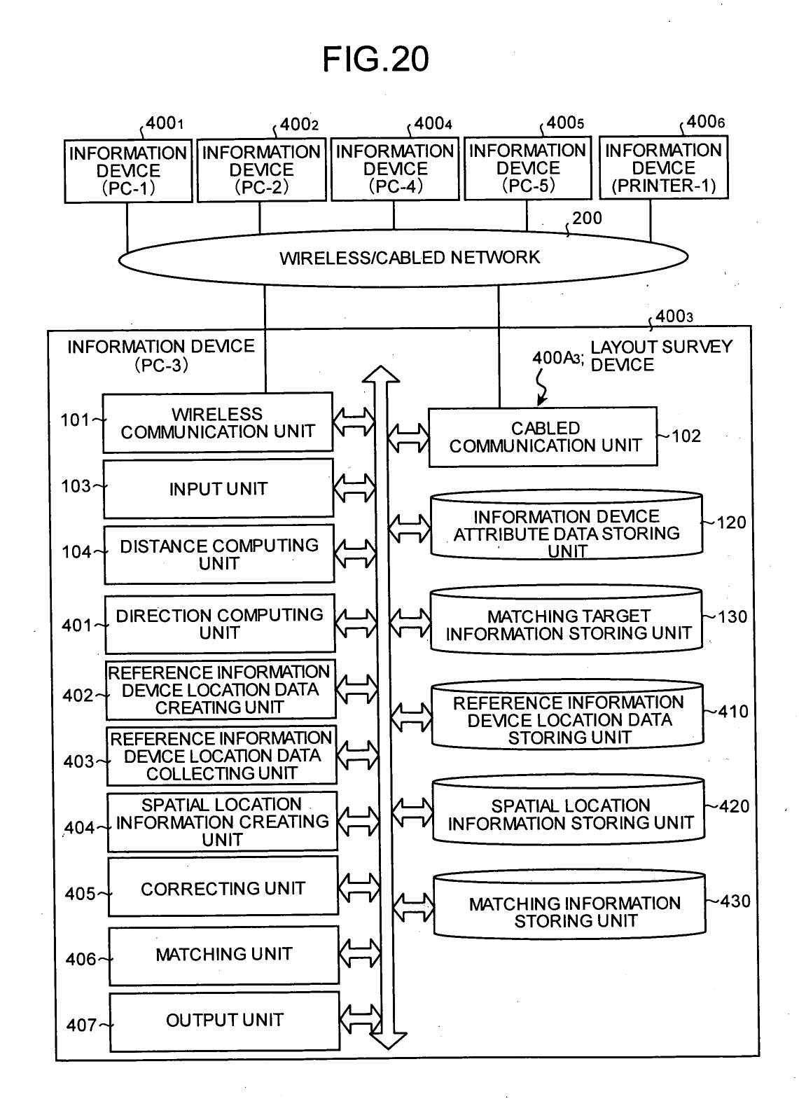

FIG. 20 is a block diagram of the layout survey system according to the second embodiment of the present invention. The layout survey system shown in FIG. 20 surveys the layout (spatial locations) of the survey objects (information devices 400₁ through 400₆), on the basis of the reception field intensity, on the basis of the distances and the directions between the information devices 400₁ through 400₆.

The parts shown in FIG. 20 that are identical to those in FIG. 1 are assigned the same reference numerals. The information devices 100₁ through 100₆ and the layout survey device 100A₃ in FIG. 1 are replaced respectively by the information devices 400₁ through 400₆ and a layout survey device 400A₃ in FIG. 20.

The information devices 400₁ through 400₆ are devices such as desktop PCs, notebook PCs, printers, etc. and are connected with each other via the wireless/cabled network 200.

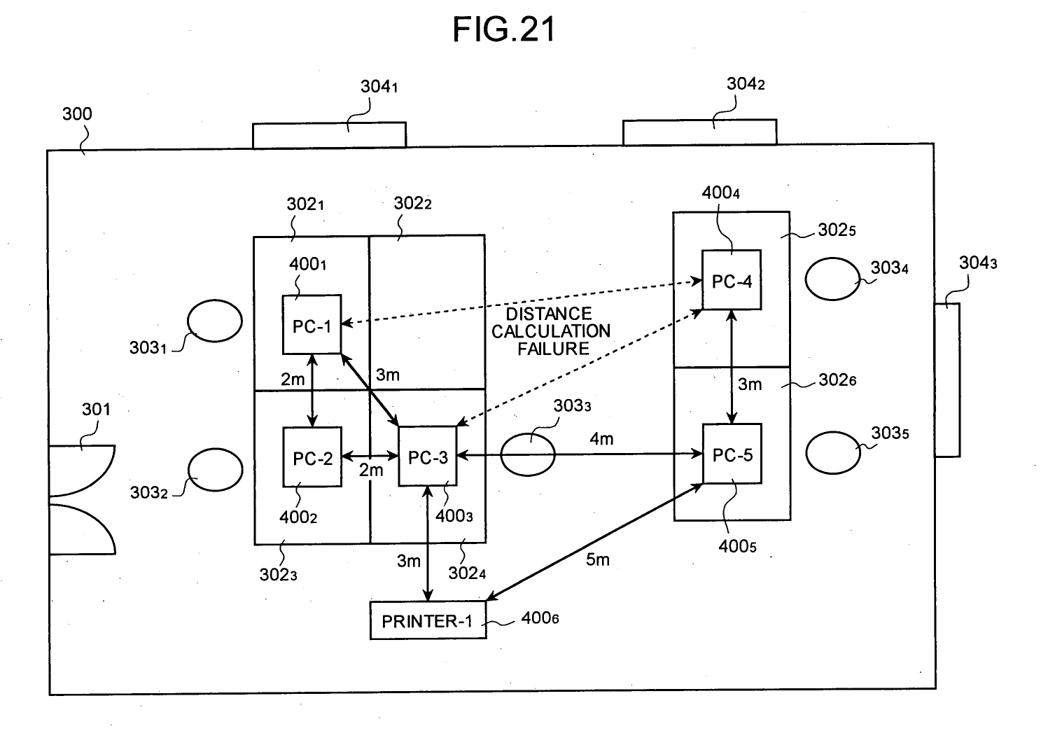

The information devices 400₁ through 400₆ are located on the office floor 300 shown in FIG. 21 and are meant to be surveyed. The parts shown in FIG. 21 that are identical to those in FIG. 2 are assigned the same reference numerals.

The information device 400₁ is a desktop PC (see FIG. 3) and is set on the desk 302₁. The information device name assigned to the information device 400₁ is “PC-1”. The information device 400₂ is a notebook PC and is set on the desk 302₃. The information device name assigned to the information device 400₂ is “PC-2”.

The information device 400₃ is again a notebook PC and is set on the desk 302₄. The information device name assigned to the information device 400₃ is “PC-3”. The information device 400₄ is a desktop PC and is set on the desk 302₅. The information device name assigned to the information device 400₄ is “PC-4”.

The information device 400₅ is again a desktop PC and is set on the desk 302₆. The information device name assigned to the information device 400₅ is “PC-5”. The information device 400₆ is a printer and is set on a surface close to the desk 302₄. The information device name assigned to the information device 4006 is “Printer-1”.

In the second embodiment, the field “Instrument device name” in the information device attribute data 121 shown in FIG. 3 corresponds to the information devices 400₁ through 400₆.

To return to FIG. 20, the information device 400₃ also includes the layout survey device 400A₃ apart from a unit that realizes the functions of a PC. The layout survey device 400A₃ is provided with the function of surveying the layout of the information devices 400₁ through 400₆. Each of the other information devices 400₁, 400₂, and 400₄ through 400₆ also are provided with a not shown layout survey device similar to the layout survey device 400A₃.

As in the first embodiment, the layout survey devices of the information devices 400₁ through 400₆ have a master-slave relationship among them. For instance, the layout survey device 400A₃ provided in the information device 400₃ is the master, and the not shown layout survey devices of the other information devices are slaves.

The parts of the layout survey device 400A₃ of the information device 400₃ shown in FIG. 20 that are identical to those shown in FIG. 1 are assigned the same reference numerals. The layout survey device 400A₃ includes a new component, that is, a direction computing unit 401.

Instead of the reference information device location data creating unit 105, the reference information device location data collecting unit 106, the spatial location information creating unit 107, the correcting unit 108, the matching unit 109, the output unit 110, the reference information device location data storing unit 140, the spatial location information storing unit 150, and the matching information storing unit 160 shown in FIG. 1, the layout survey device 400A₃ respectively has a reference information device location data creating unit 402, a reference information device location data collecting unit 403, a spatial location information creating unit 404, a correcting unit 405, a matching unit 406, an output unit 407, a reference information device location data storing unit 410, a spatial location information storing unit 420, and a matching information storing unit 430.

The direction computing unit 401 computes, on the basis of the reception field intensity, the direction between itself (the information device 400₃ in this case) and each of the other information devices 400₁, 400₂, and 400₄ through 400₆ on the basis of the information device attribute data 121 (see FIG. 3). To be specific, the direction computing unit 401 considers the direction of maximum reception field intensity for each of the information devices as the direction of that information device with respect to itself (the direction computing unit 401).

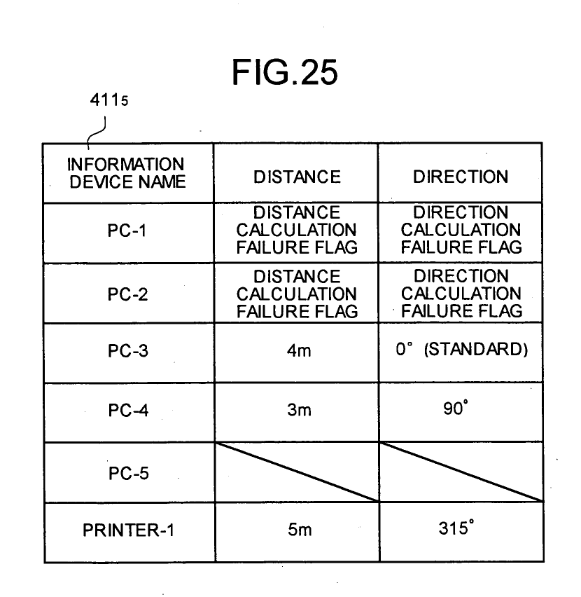

However, the direction between the information devices cannot be calculated in the following cases. Hence, in these cases a direction calculation failure flag (see FIG. 25), which is described later, is set.
When the distance between two information devices exceeds the effective wireless coverage range
When there is an obstruction between two information devices, preventing radio waves from reaching the information device
When the wireless communication units of the two information devices have different wireless systems—that is, if the wireless system of one communication unit is wireless LAN that complies with Ethernet and the wireless system of the other communication unit is Bluetooth.

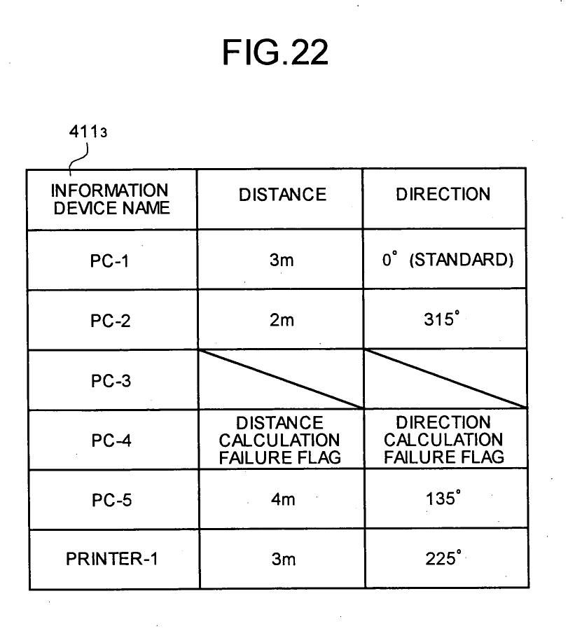

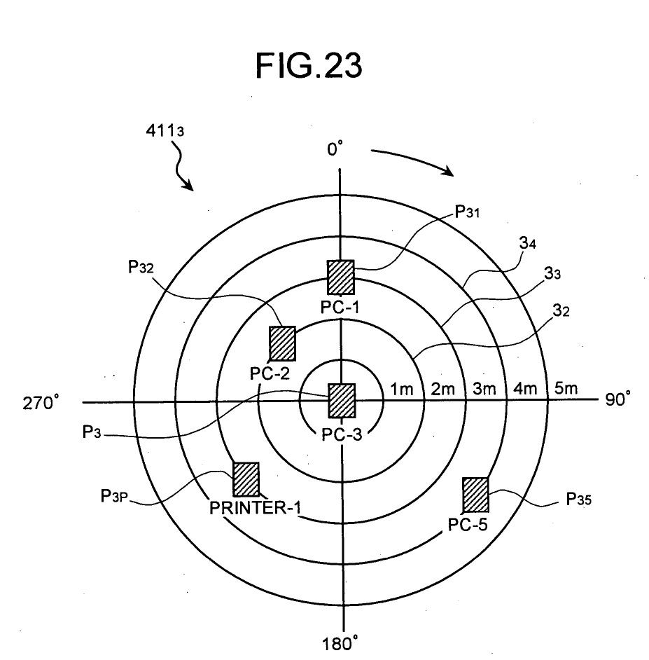

The reference information device location data creating unit 402 creates reference information device location data 411₃ (see FIG. 23) on the basis of the calculation result of the distance computing unit 104 and the direction computing unit 401. The reference information device location data 411₃ indicates where the other information devices are located with respect to the information device 400₃ (PC-3) shown in FIG. 22 considering PC-3 as the reference information device.

The reference information device location data 411₃ shown in FIG. 22 is information that indicates the distance and direction of each of the other information devices with respect to PC-3 (the reference information device). In the example shown in FIG. 22, PC-1 is at a distance of 3 m from PC-3 (the reference information device) and is located at 0° (reference) with respect to PC-3.

PC-2 is at a distance of 2 m from PC-3 (the reference information device) and is located at 315° with respect to PC-3. The distance as well as the direction between PC-3 (the reference information device) and PC-4 is not calculable (that is, both the distance calculation failure flag and a direction calculation failure flag are set).

PC-5 is at a distance of 4 m from PC-3 (the reference information device) and is located at 135° with respect to PC-3. Printer-1 is at a distance of 3 m from PC-3 (the reference information device) and is located at 225° with respect to PC-3.

FIG. 23 is a schematic diagram of the reference information device location data 411₃. In FIG. 23, concentric circles of radii in units of 1 m (viable circles 3₂, 3₃, 3₄, etc.) and corresponding to the distances shown in FIG. 22 are shown, with the reference information device (PC-3) representing the center. The direction in FIG. 22 is set clockwise from the perpendicular of PC3 shown in FIG. 22, which is taken as 0° (reference).

To be specific, in FIG. 23, PC-1 is located at position P₃₁ (Distance 3 m, Direction 0°) and PC-2 is located at position P₃₂ (Distance 2 m, Direction 315°).

PC-5 is located at position P₃₅ (Distance 4 m, Direction 135°). Printer-1 is located at position P_{3P} (Distance 3 m, Direction 225°). PC-3 is located at the center P₃.

The reference information device location data 411₃ created by the reference information device location data creating unit 402 of the information device 400₃ (PC-3) is stored in the reference information device location data storing unit 410 (see FIG. 20).

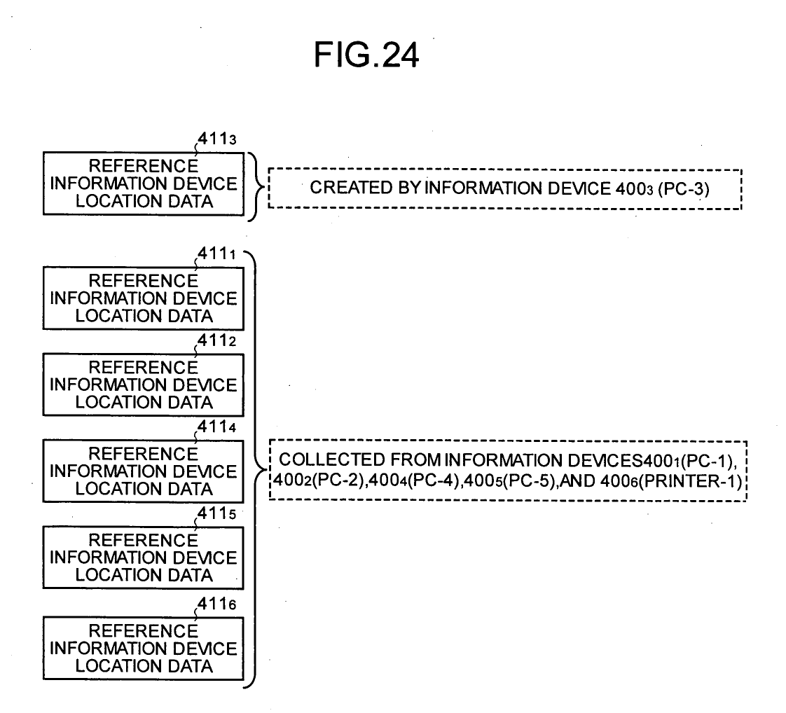

The not shown respective layout survey devices of the information device 400₁ (PC-1), 400₂ (PC-2), 400₄ (PC-4), 400₅ (PC-5), and 400₆ (Printer-1) also create, by taking their own information device as the reference information device, reference information device location data 411₁, 411₂, 411₄, 411₅, and 411₆ (see FIG. 24).

For instance, as shown in FIG. 25, the not shown layout survey device of the information device 400₅ (PC-5) creates the reference information device location data 411₅ by taking PC-5 as the reference information device.

In FIG. 25, since neither the distance nor the direction is calculable between PC-5 (the reference information device) and PC-1, the distance calculation failure flag and the direction calculation failure flag are set. Again, since neither the distance nor the direction is calculable between PC5 (the reference information device) and PC-2, the distance calculation failure flag and the direction calculation failure flag are set.

PC-3 is at a distance of 4 m from PC-5 (the reference information device) and is located at 0° with respect to PC-5. PC-4 is at a distance of 3 m from PC-5 (the reference information device) and is located at 90° with respect to PC-5. Printer-1 is at a distance of 5 m from PC-5 (the reference information device) and is located at 315° with respect to PC-5.

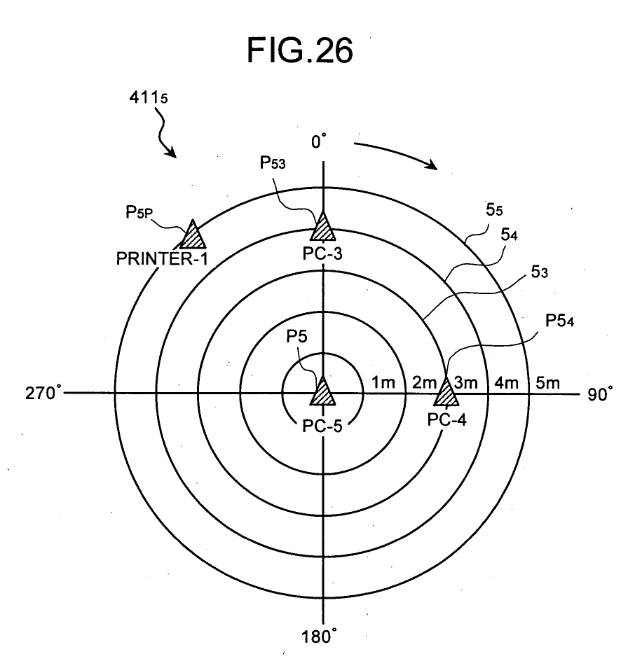

FIG. 26 is a schematic diagram of the reference information device location data 411₅. In FIG. 26, concentric circles of radii in units of 1 m (viable circles 5₂, 5₃, 5₄, etc.) and corresponding to the distances shown in FIG. 25 are shown, with the reference information device (PC-5) representing the center. The direction in FIG. 26 is set clockwise from the perpendicular of PC5 shown in FIG. 25, which is taken as 0° (reference).

To be specific, in FIG. 26, PC3 is located at position P₅₃ (Distance 4 m, Direction 0°) and PC-4 is located at position P₅₄ (Distance 3 m, Direction 90°).

Printer-1 is located at position P_{5P} (Distance 5 m, Direction 315°), and PC-5 is located at the center on P₅.

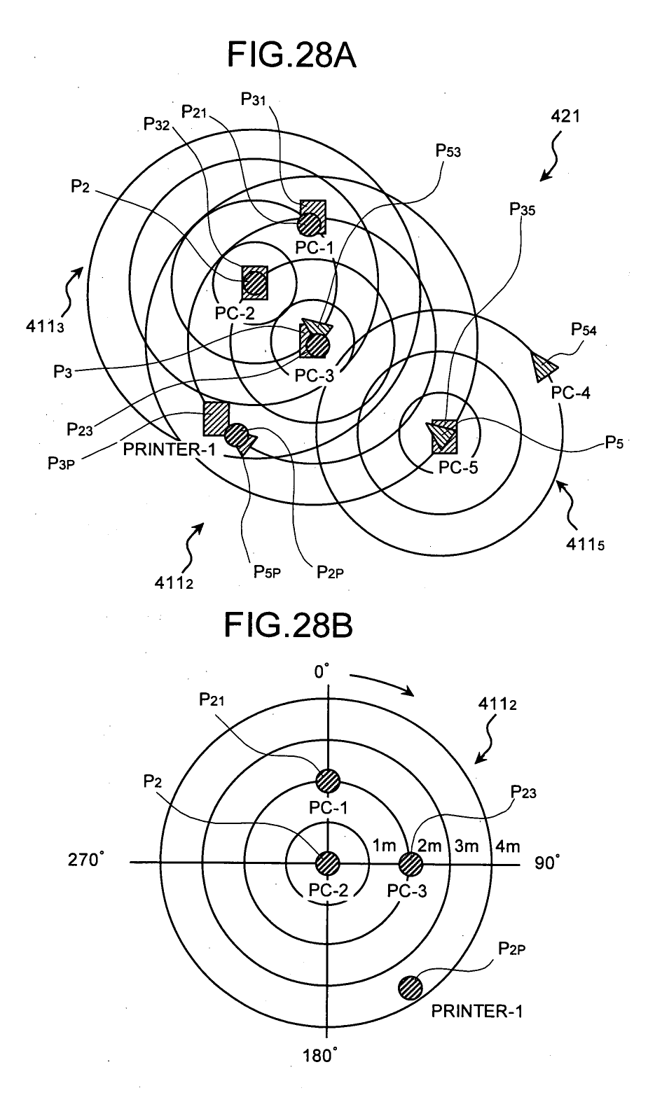

The not shown layout survey device of the information device 400₂ (PC-2) creates the reference information device location data 411₂ as shown in FIG. 28B by taking PC-2 as the reference information device.

In FIG. 28B, PC-1 is located at position P₂₁ (Distance 2 m, Direction 0°), PC-3 is located at position P₂₃ (Distance 2 m, Direction 90°), Printer-1 is located at P_{2P} (Distance 3.6 m, Direction 150°), and PC-2 is located at the center P₂.

To return to FIG. 20, the reference information device location data collecting unit 403 collects, via the cabled communication unit 102 (the wireless communication unit 101 can also be used) the reference information device location data 411₁, 411₂, 411₄, 411₅, and 411₆ from the layout survey devices of the information device 400₁ (PC-1), 400₂ (PC-2), 400₄ (PC-4), 400₅ (PC-5), and 400₆ (Printer-1) respectively, and stores the collected data in the reference information device location data storing unit 410 (see FIG. 20). In the second embodiment, the reference information device location data collecting unit 403 can store the reference information device location data in the reference information device location data storing unit 410 by correlating it to the time at which the data is created.

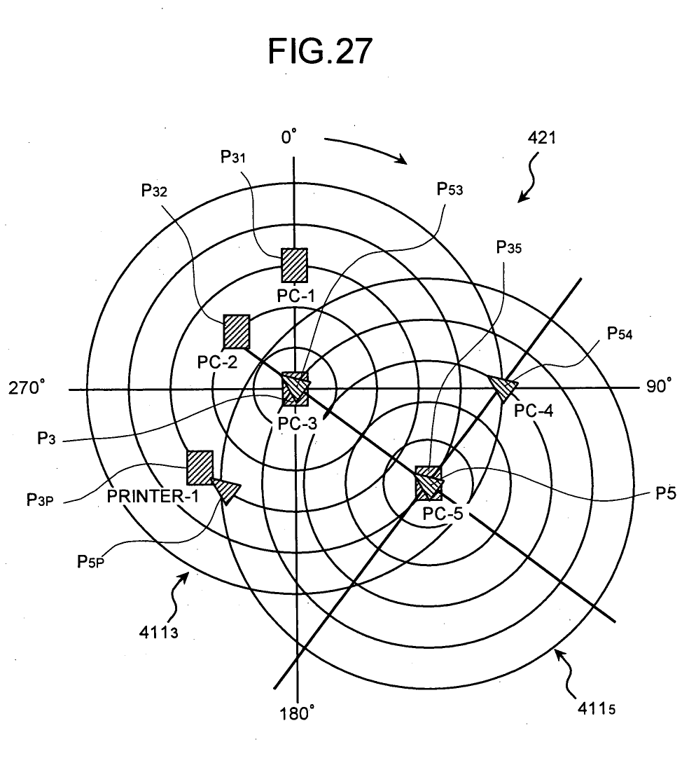

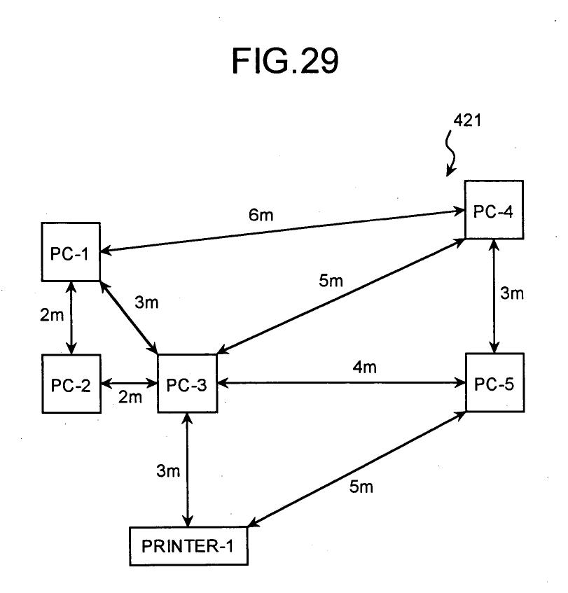

The spatial location information creating unit 404 sequentially combines the reference information device location data 411₁ through 411₆ stored in the reference information device location data storing unit 410 as shown in FIG. 27 and FIG. 28A and creates a spatial location information 421 shown in FIG. 29. The spatial location information 421 is information that indicates the spatial location (layout) of each of the information devices being surveyed, and is a survey result of the layout survey device 400A₃.

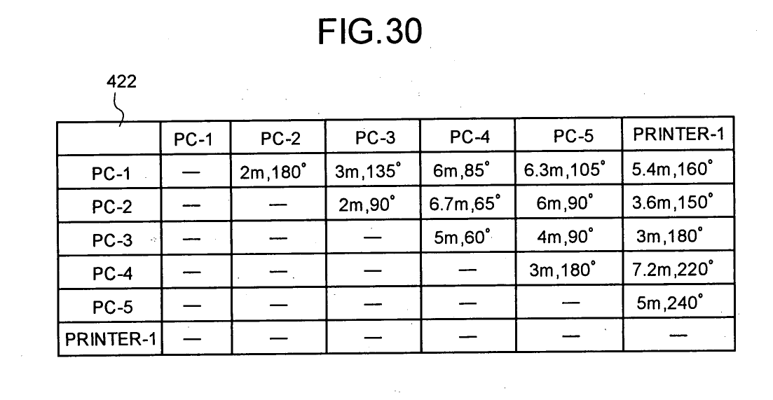

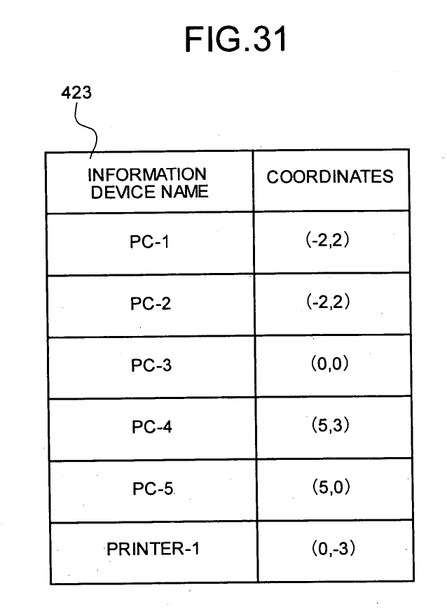

The spatial location information creating unit 404 creates a distance-direction spatial location information 422 (see FIG. 30) or a coordinate spatial location information 423 (see FIG. 31), and stores the distance-direction spatial location information 422 or the coordinate spatial location information 423 in the spatial location information storing unit 420 (see FIG. 20).

The correcting unit 405, like the correcting unit 108 (see FIG. 1) corrects the distance-direction spatial location information 422 or the coordinate spatial location information 423 stored in the spatial location information storing unit 420.

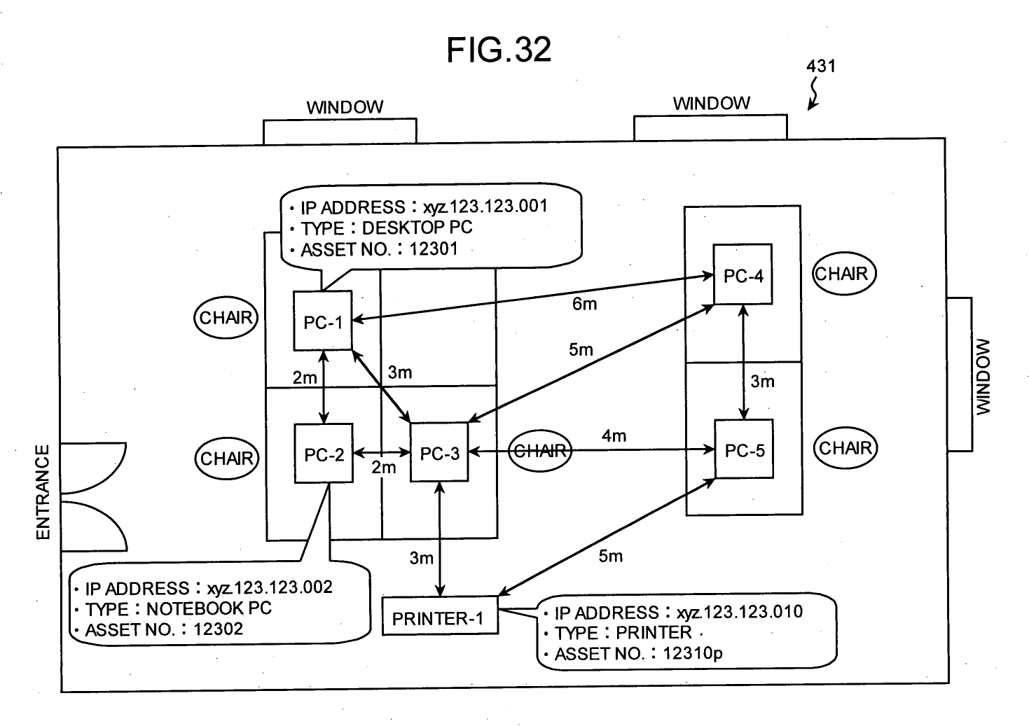

The matching unit 406 matches the matching information (for instance, the matching target information 131—see FIG. 4) stored in the matching target information storing unit 130 and the spatial location information (for instance the distance-direction spatial location information 422—see FIG. 30), creates a matching information 431 shown in FIG. 32, and stores the matching information 431 in the matching information storing unit 430 (see FIG. 20).

The output unit 407 outputs the spatial location information 421 (see FIG. 29), the distance-direction spatial location information 422 (see FIG. 30), the coordinate spatial location information 423 (see FIG. 31), and the matching information 431 (see FIG. 32).

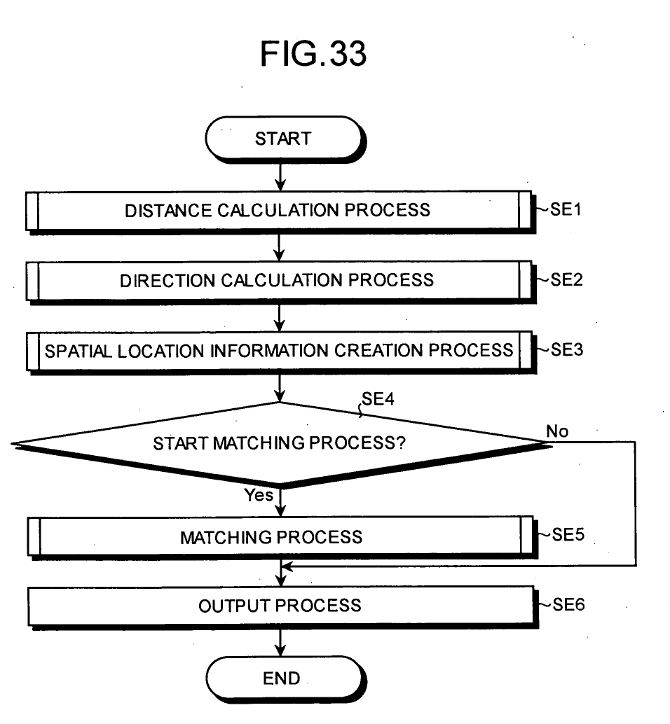

The operation of the layout survey system according to the second embodiment is explained next with reference to the flow charts shown in FIG. 33 through FIG. 36. The layout survey system in this example is shown to survey the layout (spatial locations) of the information devices 400₁ through 400₆ shown in FIG. 21.

In Step SE1 shown in FIG. 33, the layout survey system carries out a distance calculation process. The distance calculation process involves calculating the distance between the information device 400₃ (PC-3) and each of the other information devices 400₁, 400₂, and 400₄ through 400₆.

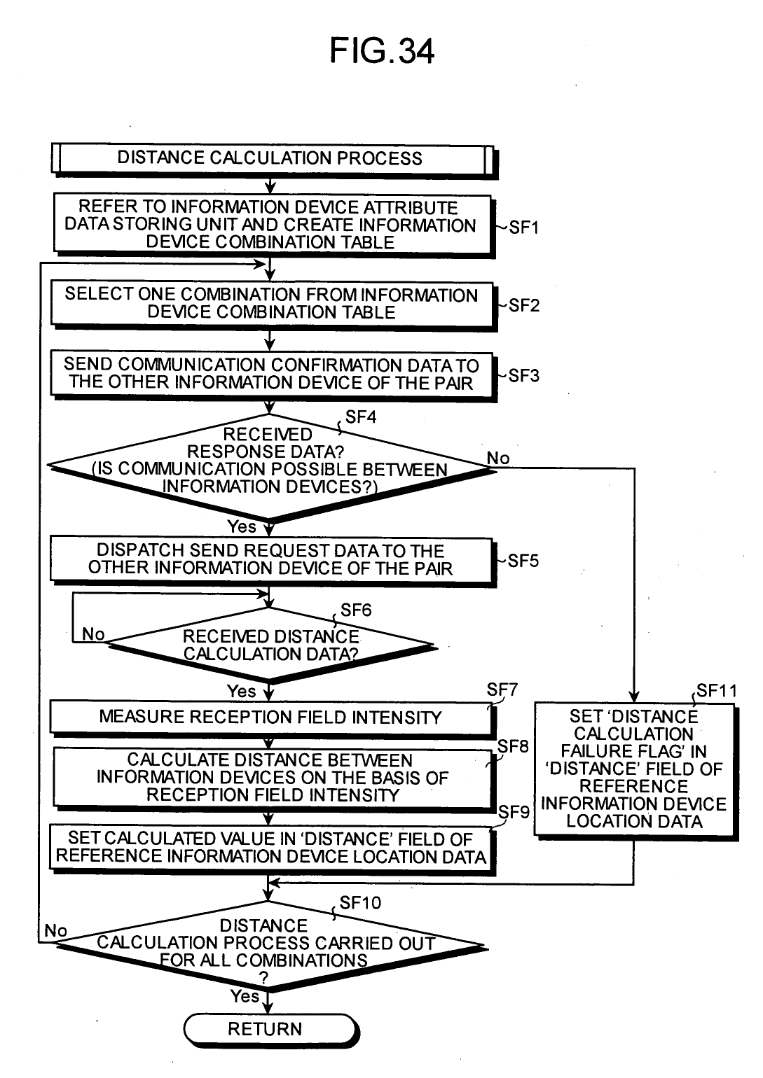

The distance calculation process is explained next FIG. 34 is a flow chart of the distance calculation process. In Step SF1, the distance computing unit 104 refers to the information device attribute data storing unit 120, and creates the information device combination table 104a shown in FIG. 5 from the information device attribute data 121 (see FIG. 3).

In Step SF2, the distance computing unit 104 selects one of the combinations from the information device combination table 104a. Let us assume that the distance computing unit 104 selects the combination with a Combination No. “1”, in which a Receiver information device is “PC-3” and a Sender information device is “PC-1”.

In Step SF3, the distance computing unit 104 sends a communication confirmation data to the other information device of the pair, that is, the sender information device PC-1 (the information device 400₁), via the wireless communication unit 101 and the wireless/cabled network 200.

The not shown layout survey device of PC-1 (the information device 400₁) receives the communication confirmation data. In response, the layout survey device of PC-1 (the information device 400₁) sends a response data to PC-3 (the information device 400₃) via the wireless/cabled network 200. The wireless communication unit 101 receives the response data.

In Step SF4, the distance computing unit 104 determines whether the response data has been received, that is, whether communication is possible between the communication devices (PC-3 and PC-1, in this case).

If the answer in Step SF4 is “No”, the distance calculation process proceeds to Step SF11. In Step SF11, the reference information device location data creating unit 402 sets the “Distance calculation failure flag” in the “Distance” field (corresponding to PC-4, in this case) of the reference information device location data 411₃ shown in FIG. 22.

If the answer in Step SF4 is “Yes”, the distance calculation process proceeds to Step SF5. In Step SF5, the distance computing unit 104 sends a send request data, requesting for distance calculation data, to the sender information device PC-1 (the information device 400₁), via the wireless communication unit 101 and the wireless/cabled network 200.

The not shown layout survey device of PC-1 (the information device 400₁) receives the send request data. In response, the layout survey device of PC-1 (the information device 400₁) sends the distance calculation data to PC-3 (the information device 400₃) via the wireless/cabled network 200.

In Step SF6, the distance computing unit 104 determines whether the distance calculation data has been received by the wireless communication unit 101. If the answer in Step SF6 is “No”, the distance computing unit 104 repeats Step SF6.

If the answer in Step SF6 is “Yes”, the distance calculation process proceeds to Step SF7. In Step SF7, the distance computing unit 104 measures the reception field intensity of the distance calculation data. In Step SF8, the distance computing unit 104 calculates using a known expression and on the basis of the reception field intensity, the distance, say 3 m (see FIG. 21) between the two information devices (PC-3 and PC-1, in this case).

In Step SF9, the distance computing unit 104 sets “3 m” in the “Distance” field (corresponding to PC-1, in this case) of the reference information device location data 411₃ shown in FIG. 22.

In Step SF10, the distance computing unit 104 determines whether the distance calculation process has been carried out for all the combinations in the information device combination table 104a shown in FIG. 5.

If the answer in Step SF10 is “No”, the distance calculation process goes back to Step SF2. In Step SF2, the distance computing unit 104 selects the combination with the Combination No. “2”, in which the Receiver information device is “PC-3” and the Sender information device is “PC-2”. The subsequent Steps SF3 through SF8 are the same as described earlier. In Step SF9, the distance computing unit 104 sets “2 m” calculated in Step SF8 in the “Distance” field (corresponding to PC-2, in this case) of the reference information device location data 411₃ shown in FIG. 22.

If the answer in Step SF10 is “No”, the distance computing unit 104 repeats Steps SF2 through SF10 for each of the unprocessed combinations from the information device combination table 104a.

If the answer in Step SF10 is “Yes”, the distance computing unit 104 ends the distance calculation process.

To return to FIG. 33, in Step SE2, the direction computing unit 401 of the information device 400₃ (PC-3) shown in FIG. 20 carries out the direction calculation process between the information device 400₃ and the other information devices 400₁, 400₂, and 400₄ through 400₆.

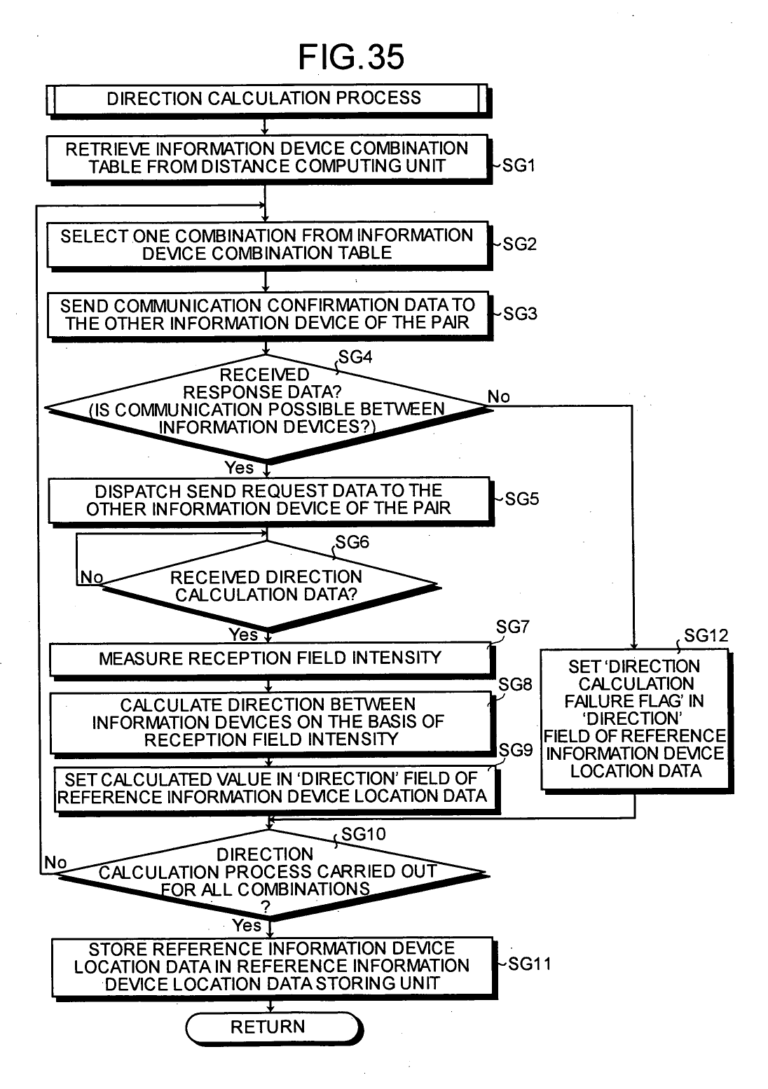

The direction calculation process is explained next. FIG. 35 is a flow chart of the direction calculation process. In Step SG1, the direction computing unit 401 retrieves the information device combination table 104a (see FIG. 5) from the distance computing unit 104.

In Step SG2, the direction computing unit 401 selects the combination having the Combination No. “1”, the Receiver information device “PC-3”, and the Sender information device “PC-1” from the information device combination table 104a.

In Step SG3, the direction computing unit 401 sends a communication confirmation data to PC-1 (the information device 400₁), that is, the sender information device, via the wireless communication unit 101 and the wireless/cabled network 200.

The not shown layout survey device of PC-1 (the information device 400₁) receives the communication confirmation data. In response, the layout survey device of PC-1 (the information device 400₁) sends a response data to PC-3 (the information device 400₃) via the wireless/cabled network 200. The wireless communication unit 101 receives the response data.

In Step SG4, the direction computing unit 401 determines whether the response data has been received, that is, whether communication is possible between the communication devices (PC-3 and PC-1, in this case).

If the answer in Step SG4 is “No”, the direction calculation process proceeds to Step SG12. In Step SG12, the reference information device location data creating unit 402 sets the “Direction calculation failure flag” in the “Direction” field (corresponding to PC-4, in this case) of the reference information device location data 411₃ shown in FIG. 22.

If the answer in Step SG4 is “Yes”, the direction calculation process proceeds to Step SG5. In Step SG5, the direction computing unit 401 sends a send request data, requesting for information required for direction calculation (hereinafter, “direction calculation data”), to the sender information device PC-1 (the information device 400₁), via the wireless communication unit 101 and the wireless/cabled network 200.

The not shown layout survey device of PC-1 (the information device 400₁) receives the send request data. In response, the layout survey device of PC-1 (the information device 400₁) sends the direction calculation data to PC-3 (the information device 400₃) via the wireless/cabled network 200.

In Step SG6, the direction computing unit 401 determines whether the direction calculation data has been received by the wireless communication unit 101. If the answer in Step SG6 is “No”, the distance computing unit 104 repeats Step SG6.

If the answer in Step SG6 is “Yes”, the direction calculation process proceeds to Step SG7. In Step SG7, the direction computing unit 401 measures the reception field intensity of the direction calculation data. In Step SG8, the direction computing unit 401 calculates the direction of maximum reception field intensity, for instance 0° (see FIG. 22), as the direction of PC-1 with respect to PC-3.

In Step SG9, the reference information device location data creating unit 402 sets in the “Direction” field (corresponding to PC-1, in this case) of the reference information device location data 411₃ shown in FIG. 22.

In Step SG10, the direction computing unit 401 determines whether the direction calculation process has been carried out for all the combinations in the information device combination table 104a shown in FIG. 5.

If the answer in Step SG10 is “No”, the direction calculation process goes back to Step SG2. In Step SG2, the direction computing unit 401 selects the combination with the Combination No. “2”, in which the Receiver information device is “PC-3” and the Sender information device is “PC-2”. The subsequent Steps SG3 through SG8 are the same as described earlier. In Step SG9, the direction computing unit 401 sets “315°” calculated in Step SG8 in the “Direction” field (corresponding to PC-2, in this case) of the reference information device location data 411₃ shown in FIG. 22.

If the answer in Step SG10 is “No”, the direction computing unit 401 repeats Steps SG2 through SG10 for each of the unprocessed combinations from the information device combination table 104a.

If the answer in Step SG10 is “Yes”, the direction calculation process proceeds to Step SG11. In Step SG11, the reference information device location data creating unit 402 stores the reference information device location data 411₃ in the reference information device location data storing unit 410. The direction calculation process ends here.

The layout survey devices of the other information devices, namely PC-1 (the information device 400₁), PC-2 (the information device 400₂), PC-4 (the information device 400₄), PC-5 (the information device 400₅), and Printer-1 (the information device 400₆) similarly carry out the direction calculation process, and respectively create and store the reference information device location data 411₁, 411₂, 411₄, 411₅, and 411₆ (see FIG. 24) created by taking respective information device as the reference information device.

To return to FIG. 33, in Step SE3, the layout survey system carries out a spatial location information creation process to create the spatial location information (the spatial location information 421 (see FIG. 29), the distance-direction spatial location information 422 (see FIG. 30), and the coordinate spatial location information 423 (see FIG. 31)) that indicates the spatial locations (layout) of the information devices 400₁ through 400₆ shown in FIG. 21.

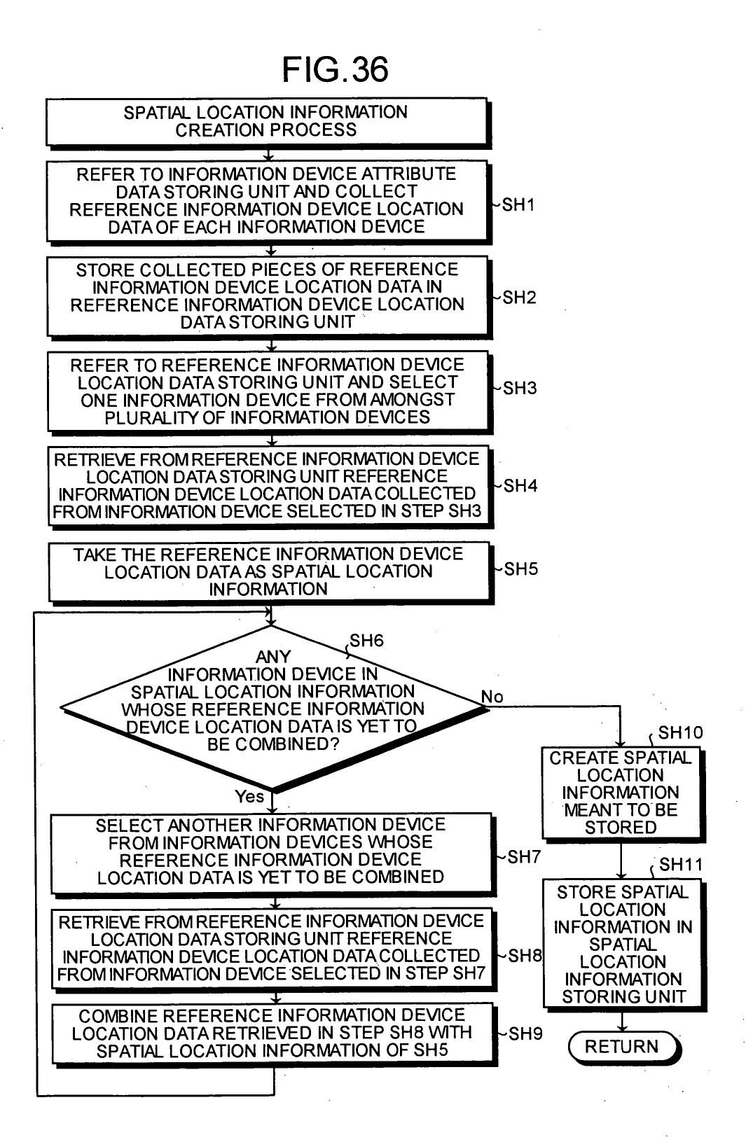

The spatial location information creation process is described next. FIG. 36 is a flow chart of the spatial location information creation process. In Step SH1, the reference information device location data collecting unit 403 refers to the information device attribute data 121 shown in FIG. 3, and collects from all the information devices except PC-3 (the information device 400₃), that is from PC-1. (the information device 400₁), PC-2 (the information device 400₂), PC-4 (the information device 400₄), PC-5 (the information device 400₅), and Printer-1 (the information device 400₆), the respective reference information device location data 411₁, 411₂, 411₄, 411₅, and 411₆ (see FIG. 24) via the wireless/cabled network 200.

In Step SH2, the reference information device location data collecting unit 403 stores the collected reference information device location data 411₁, 411₂, 411₄, 411₅, and 411₆ in the reference information device location data storing unit 410.

In Step SH3, the spatial location information creating unit 404 refers to the information device attribute data storing unit 120, and selects one information device, for instance PC-3 (the information device 400₃) out of a plurality of information devices.

In Step SH4, the spatial location information creating unit 404 retrieves from the reference information device location data storing unit 410 the reference information device location data 411₃ (see FIG. 23).

In Step SH5, the spatial location information creating unit 404 takes the reference information device location data 411₃ as the spatial location information.

In Step SH6, the spatial location information creating unit 404 checks whether any information device remains whose reference information device location data has not been combined yet (the first time checking is done for the reference information device location data 411₃ shown in FIG. 23. Subsequently, checking is done for the spatial location information 421 updated in Step SH9). The answer in Step SH6 is “Yes” since there are information devices whose reference information device location data are yet to be combined.

In the example shown in FIG. 23, the reference information device location data of the information devices PC-1, PC-2, PC-5, and Printer-1 are yet to be combined.

In Step SH7, the spatial location information creating unit 404 selects one information device, for instance, PC-5, from among those (PC-1, PC-2, PC-5, and Printer-1) whose reference information device location data have not been combined.

In Step SH8, the spatial location information creating unit 404 retrieves from the reference information device location data storing unit 410 the reference information device location data 411₅ shown in FIG. 25 and FIG. 26 collected from PC-5 (the information device 400₅).

In Step SH9, the spatial location information creating unit 404 combines, as shown in FIG. 27, the reference information device location data 411₅ retrieved in Step SH8 with the latest spatial location information (reference information device location data 411₃ (see FIG. 23)) and updates the spatial location information 421 (see FIG. 27).

When combining the reference information device location data 411₅ with the reference information device location data 411₃, the spatial location information creating unit 404 turns the reference information device location data 411₅ in such a way that:
Position P₃ corresponding to PC-3 coincides with Position P₅₃
Position P₅ corresponding to PC-5 coincides with Position P₃₅
Position P_{3P} corresponding to Printer-1 coincides with Position P_{5P}

To return to FIG. 36, the spatial location information creation process returns to Step SH6 and again determines whether any information device is left in the spatial location information 421 shown in FIG. 27 whose reference information device location data remains to be combined. Since reference information device location data PC-1, PC-2, and Printer-1 still remain to be combined, the answer in Step SH6 is “Yes”.

The spatial location information creating unit 404 repeats Steps SH7 through SH9 until the answer in Step SH6 is “No”. The spatial location information 421 is updated sequentially and in the end the spatial location information 421 shown in FIG. 29 is created. FIG. 29 is a schematic drawing of the spatial locations (layout) of the information devices being surveyed.

If the answer in Step SH6 is “No”, the spatial location information creation process proceeds to Step SH10. In Step SH10, the spatial location information creating unit 404 creates from the spatial location information 421 shown in FIG. 29 the distance-direction spatial location information 422 shown in FIG. 30 meant to be stored.

The distance-direction spatial location information 422 contains the distance and direction between each pair of information devices in the form of a matrix. For instance, as shown in FIG. 29, the distance between PC-1 and PC-2 is 2 m and the direction is 180° (that is, if the perpendicular of PC-1 is taken as a reference 0°, PC-2 is located 180° clockwise with respect to PC-1).

Alternatively, in the second embodiment, the spatial location information creating unit 404 can create from the spatial location information 421 shown in FIG. 29 the coordinate spatial location information 423 shown in FIG. 31 meant to be stored. In the coordinate spatial location information 423, the location of each of the information devices is represented by coordinates in a two-dimensional coordinate system with respect to the location of PC-3 shown in FIG. 29, whose coordinates are taken to be (0,0).

To return to FIG. 36, in Step SH11, the spatial location information creating unit 404 stores the distance-direction spatial location information 422 (see FIG. 30) or the coordinate spatial location information 423 (see FIG. 31) in the reference information device location data storing unit 410. The spatial location information creation process ends here.

To return to FIG. 33, in Step SE4, the layout survey system determines whether a matching process is to be carried out. If the answer in Step SE4 is “No”, the layout survey system proceeds to Step SE6. In Step SE6, the output unit 110 retrieves from the spatial location information storing unit 420 and outputs the distance-direction spatial location information 422 (see FIG. 30) or the coordinate spatial location information 423 (see FIG. 31).

If the answer in Step SE4 is “Yes”, the layout survey system proceeds to Step SE5. In Step SE5 the layout survey system carries out the matching process to match the matching target information and the spatial location information.

The matching process is explained next with reference to FIG. 19. In Step SD1, the matching unit 406 retrieves the distance-direction spatial location information 422 shown in FIG. 30 or the coordinate spatial location information 423 shown in FIG. 31 from the spatial location information storing unit 420.

In Step SD2, the user can specify as the matching target information, say, the matching target information 131 (see FIG. 4) and the information device attribute data 121 (see FIG. 3) by means of the input unit 103. In Step SD3, the matching unit 406 retrieves from the respective storing units (in this case, from the matching target information storing unit 130 and the information device attribute data storing unit 120) the matching target information 131 and the information device attribute data 121 specified in Step SD2.

In Step SD4, the matching unit 406, matches the distance-direction spatial location information 422 (see FIG. 30) retrieved in Step SD1, and the matching target information 131 (see FIG. 4) as well as the information device attribute data 121 (see FIG. 3) retrieved in Step SD3, and creates the matching information 431 shown in FIG. 32.

The matching information 431 contains the information device attribute data (IP address, Type, and Asset No.) of each of the information devices (PC-1, PC-2, etc.) correlated to the respective information device.

In Step SD5, the matching unit 406 stores the matching information 431 (see FIG. 32) in the matching information storing unit 430. The matching process ends here. To return to FIG. 33, the layout survey system proceeds to Step SE6. In Step SE6, the output unit 407 retrieves from the matching information storing unit 430 and outputs the matching information 431 (see FIG. 32).

In the second embodiment, only a relative direction of each information devices with respect to other information devices is calculated, stored and output. However, if geomagnetism can be measured using a magnet, the direction specified by the magnet (for instance, EW) can be output as well as the relative direction.

Thus, one of a plurality of survey objects (the information devices 400₁ through 400₆), the information device 400₃ in this case, is taken as the reference survey object. The distance and direction between the reference survey object and each of the other survey objects are calculated on the basis of the reception field intensity. The reference information device location data 411₃ (see FIG. 22 and FIG. 23) that indicates the layout is created on the basis of the distances and the directions of the other survey objects with respect to the reference survey object. Similarly, by taking each of the other survey objects as the reference survey object, the reference information device location data 411₁, 411₂, and 411₄ through 411₆ are created. The reference information device location data thus created are combined to create the spatial location information 421 etc. (see FIG. 29) that indicates the layout of the survey objects. Thus, the layout of the survey objects can be surveyed quickly and accurately.

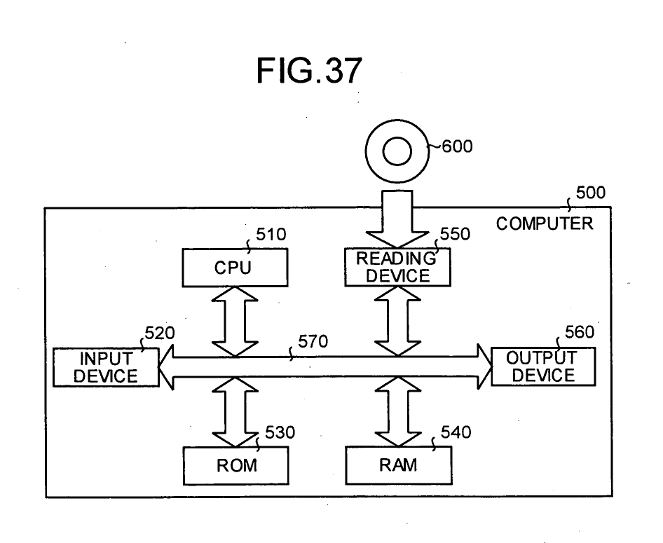

Alternatively, as shown in FIG. 37, a program that executes the layout survey function can be recorded on a computer-readable recording medium 600. A computer 500 can load the program from the recording medium 600 and execute the layout survey function of the layout survey device 100A₃ as well as the other not shown layout survey devices and the layout survey device 400A₃ as well as the other not shown layout survey devices.

The computer 500 includes a central processing unit (CPU) 510, input devices 520 such as a keyboard, a mouse, etc., a Read-Only Memory (ROM) 530 that stores various kinds of data, a Random Access Memory (RAM) that stores calculation parameters, etc., a reading device 550 that reads the program from the recording medium 600, output devices 560 such as a display, printer, etc., and a bus 570 that connects all the parts mentioned above.

The CPU 510 and the reading device 550 read and execute the program recorded on the recording medium 600, thus realizing the layout survey function. The recording medium 600 can be an optical disk, a flexible disk, a hard disk, etc.

The distance and direction in the first embodiment and the second embodiment can be calculated according to the following schedule on the basis of the “Proneness to shifting” field of the information device attribute data 121 (see FIG. 3).
Distance and direction for those information devices that are seldom shifted (Fixed) can be calculated once a month or so.
Distance and direction for those information devices that are infrequently shifted (Substantially fixed) can be calculated once a week or so.
Distance and direction for those information devices that are frequently moved (Frequently shifted) can be calculated every hour or so.

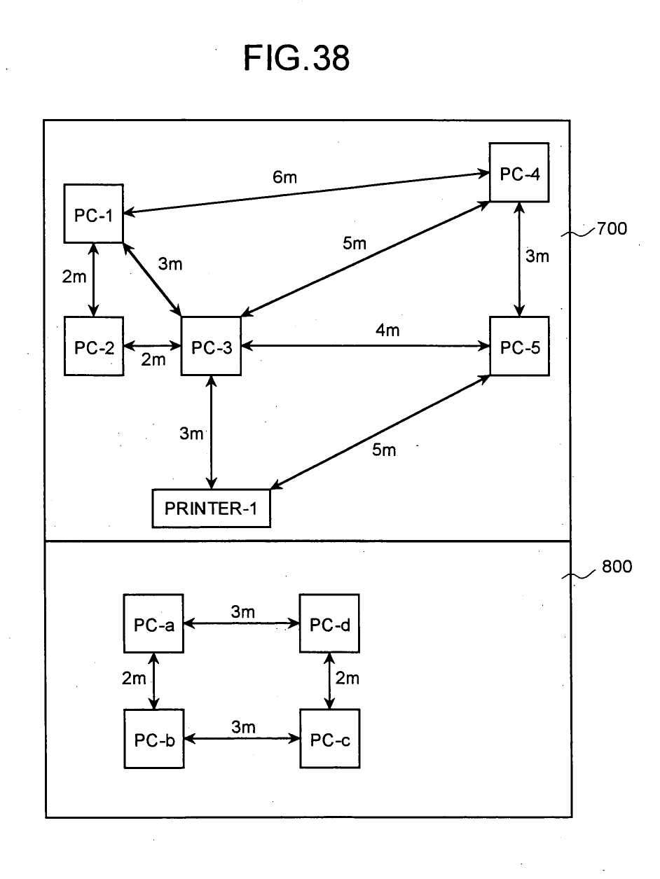

When the information devices being surveyed are set in spaces 700 and 800 shown in FIG. 38, the layout survey apparatus according to the first embodiment and the second embodiment can create the information device attribute data for each of the spaces 700 and 800 and carry out the survey for each of the spaces 700 and 800 independently using the respective information device attribute data.

In the layout survey system according to the first embodiment and the second embodiment, if there is a shift in the location of a particular information device when combining a plurality of reference information device location data in the spatial location information creation step, the median point of the locations can be determined or the distance and direction can be recalculated.

In the layout survey system according to the first embodiment and the second embodiment, if the distance and direction cannot be calculated by radio waves, they can calculated mathematically using other calculated distances and directions.

In the layout survey system according to the first embodiment and the second embodiment, information devices were taken as the survey objects. However, any article can be taken as the survey object as long as the layout survey device can be connected to it (either internally or externally).

In the layout survey apparatus according to the first embodiment and the second embodiment, the spatial location information creating units 107 and 404 can determine the difference between the previously created spatial location information (layout information) and the current spatial location information (layout information) to check if any survey object has been shifted. In this way, the status of shifting of the survey object can be more accurately determined.

Thus, according to the present invention, a distance between a computer and a plurality of other devices is calculated respectively on the basis of a reception field intensity. Location data of the computer and the devices is created on the basis of the distance calculated, and also acquired from the devices respectively. Layout information for displaying physical layout of the computer and the devices is created on the basis of the location data created and acquired. Consequently, the layout of the survey objects can be surveyed quickly and accurately.

According to the present invention, a distance and a direction between a computer and a plurality of other devices are calculated respectively on the basis of a reception field intensity. Location data of the computer and the devices is created on the basis of the distance and the direction calculated, and also acquired from the devices respectively. Layout information for displaying physical layout of the computer and the devices is created on the basis of the location data created and acquired. Consequently, the layout of the survey objects can be surveyed quickly and accurately.

According to the present invention, associated information about the computer and the devices is received and the layout information is created on the basis of the location data created, the location data acquired, and the associated information. Consequently, the association between the associated information and the survey objects can be clearly defined, thereby enhancing user-friendliness.

According to the present invention, the associated information includes layout information of a place where the computer and the devices are located. Consequently, the association between the environment and the survey objects can be clearly defined, thereby enhancing user-friendliness.

According to the present invention, the associated information includes attributes of the computer and the devices. Consequently, the association between the attribute data and the survey objects can be clearly defined, thereby enhancing user-friendliness.

According to the present invention, the layout information is corrected. Consequently, minute adjustments can be made in the layout information according to the actual layout.

According to the present invention, a device whose location is different from the location in layout information that is previously created is decided, and the layout information is displayed in which the device whose location is decided to be different is displayed in a different form. Consequently, the status of shifting of the survey objects can be more accurately determined.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

1. A computer-readable recording medium that stores a computer program that causes a computer to execute:
calculating a distance between the computer and a plurality of other devices respectively on the basis of a reception field intensity;
creating location data of the computer and the devices on the basis of the distance calculated;
acquiring location data of the computer and the devices from the devices respectively; and
creating layout information for displaying physical layout of the computer and the devices on the basis of the location data created and the location data acquired.

2. The computer-readable recording medium according to claim 1, wherein the computer program further causes the computer to execute:
receiving associated information about the computer and the devices, wherein
the layout information is created on the basis of the location data created, the location data acquired, and the associated information.

3. The computer-readable recording medium according to claim 2, wherein the associated information includes layout information of a place where the computer and the devices are located.

4. The computer-readable recording medium according to claim 2, wherein the associated information includes attributes of the computer and the devices.

5. The computer-readable recording medium according to claim 1, wherein the computer program further causes the computer to execute correcting the layout information.

6. The computer-readable recording medium according to claim 1, wherein the computer program further causes the computer to execute:
deciding a device whose location is different from the location in layout information that is previously created; and
displaying the layout information in which the device whose location is decided to be different is displayed in a different form.

7. A computer-readable recording medium that stores a computer program that causes a computer to execute:
calculating a distance and a direction between the computer and a plurality of other devices respectively on the basis of a reception field intensity;
creating location data of the computer and the devices on the basis of the distance and the direction calculated;
acquiring location data of the computer and the devices from the devices respectively; and
creating layout information for displaying physical layout of the computer and the devices on the basis of the location data created and the location data acquired.

8. The computer-readable recording medium according to claim 7, wherein the computer program further causes the computer to execute:
receiving associated information about the computer and the devices, wherein
the layout information is created on the basis of the location data created, the location data acquired, and the associated information.

9. The computer-readable recording medium according to claim 8, wherein the associated information includes layout information of a place where the computer and the devices are located.

10. The computer-readable recording medium according to claim 8, wherein the associated information includes attributes of the computer and the devices.

11. The computer-readable recording medium according to claim 7, wherein the computer program further causes the computer to execute correcting the layout information.

12. The computer-readable recording medium according to claim 7, wherein the computer program further causes the computer to execute:
deciding a device whose location is different from the location in layout information that is previously created; and
displaying the layout information in which the device whose location is decided to be different is displayed in a different form.

13. A layout survey apparatus comprising:
a calculating unit that calculates a distance to a plurality of other devices respectively on the basis of a reception field intensity;
a creating unit that creates location data of the apparatus and the devices on the basis of the distance calculated;
an acquiring unit that acquires location data of the apparatus and the devices from the devices respectively; and
a creating unit that creates layout information for displaying physical layout of the apparatus and the devices on the basis of the location data created and the location data acquired.

14. A layout survey method comprising:
calculating a distance between a first device and a plurality of second devices respectively on the basis of a reception field intensity;
creating location data of the first device and the second devices on the basis of the distance calculated;
acquiring location data of the first device and the second devices from the second devices respectively; and
creating layout information for displaying physical layout of the first device and the second devices on the basis of the location data created and the location data acquired.

15. A layout survey system comprising:
a master device; and
a plurality of slave devices, wherein the master device includes
a calculating unit that calculates a distance between the master device and the slave devices respectively on the basis of a reception field intensity;
a creating unit that creates location data of the master device and the slave devices on the basis of the distance calculated;
an acquiring unit that acquires location data of the master device and the slave devices from the slave devices respectively; and
a creating unit that creates layout information for displaying physical layout of the master device and the slave devices on the basis of the location data created and the location data acquired.
